(19) United States
(12) Patent Application Publication
(10) Pub. No.: US 2025/0176115 A1
(43) Pub. Date: May 29, 2025

(54) PANEL BODY, DISPLAY DEVICE, AND METHOD FOR MANUFACTURING PANEL BODY

(71) Applicant: Panasonic Automotive Systems Co., Ltd., Kanagawa (JP)

(72) Inventors: Ryota MIZUNO, Kanagawa Ken (JP); Takashi ICHIHARA, Kanagawa Ken (JP); Yuki WATANABE, Kanagawa Ken (JP); Yusuke KUROKAWA, Shiga Ken (JP); Suguru FURUICHI, Shiga Ken (JP)

(73) Assignee: Panasonic Automotive Systems Co., Ltd., Kanagawa (JP)

(21) Appl. No.: 19/039,326

(22) Filed: Jan. 28, 2025

Related U.S. Application Data
(63) Continuation of application No. PCT/JP2023/040458, filed on Nov. 9, 2023.

(30) Foreign Application Priority Data
Nov. 29, 2022 (JP) 2022-189822
Nov. 29, 2022 (JP) 2022-189849

(51) Int. Cl. H05K 5/02; B29C 45/00; B29C 45/14; B29K 105/12; B29K 307/04; B29L 31/34

(52) U.S. Cl. CPC H05K 5/02; B29C 45/0005; B29C 45/14065; B29C 45/1418; B29C 45/14336; B29K 2105/12; B29K 2307/04; B29K 2995/002; B29L 2031/3475

(57) ABSTRACT

A panel body includes a plate-shaped member and a frame body. The frame body is made of a carbon fiber-reinforced resin and integrally molded with the plate-shaped member. The frame body covers an end surface of the plate-shaped member without discontinuity.

### CROSS-REFERENCE TO RELATED APPLICATIONS

This application is a continuation of International Application No. PCT/JP2023/040458, filed on Nov. 9, 2023 which claims the benefit of priority of the prior Japanese Patent Application Nos. 2022-189822 and 2022-189849, both filed on Nov. 29, 2022, the entire contents of which are incorporated herein by reference.

### FIELD

Embodiments described herein relate generally to a panel body, a display device, and a method for manufacturing the panel body.

### BACKGROUND

A panel body made of glass may be used for a display device such as a monitor for a navigation system. There is a demand for a display device having a large screen, which makes it difficult to handle a plate-shaped member made of glass or the like used for a panel body during transportation and assembly. In addition, in a case where the display device is mounted on a vehicle or the like, in order to meet strict safety standards established for preventing a crack and a chip in the plate-shaped member, and it is required to avoid damage caused by slight twisting that occurs when the plate-shaped member is assembled.

A related technique is described in JP 2019-150990 A.

The present disclosure has an object to provide a panel body easy to handle, a display device, and a method for manufacturing the panel body.

### SUMMARY

A panel body according to the present disclosure includes a plate-shaped member and a frame body. The frame body is made of a carbon fiber-reinforced resin and integrally molded with the plate-shaped member. The frame body covers an end surface of the plate-shaped member without discontinuity.

### BRIEF DESCRIPTION OF THE DRAWINGS

FIG. 1A is a perspective view of a panel body according to an embodiment as viewed from a first surface side;

FIG. 1B is a perspective view of the panel body according to the embodiment as viewed from a second surface side;

FIG. 1C is a partially enlarged cross-sectional view of the panel body according to the embodiment;

FIG. 2 is a schematic view illustrating an example of a configuration of a molding apparatus used for manufacturing the panel body according to the embodiment;

FIG. 3 is a perspective view illustrating an example of an internal structure of a mold used for manufacturing the panel body according to the embodiment;

FIG. 4A is a view for explaining an example of a method for manufacturing a panel body;

FIG. 4B is a view for explaining the example of the method for manufacturing the panel body;

FIG. 4C is a view for explaining the example of the method for manufacturing the panel body;

FIG. 5A is a view for explaining an example of a frame body;

FIG. 5B is a view for explaining an example of a frame body;

FIG. 5C is a view for explaining an example of a frame body;

FIG. 6 is a view illustrating an example of a temperature condition of the molding apparatus when the frame body according to the embodiment is integrally molded with the plate-shaped member;

FIG. 7A is a perspective view of a panel body as viewed from a first surface side;

FIG. 7B is a perspective view of the panel body as viewed from a second surface side;

FIG. 7C is a top view of the panel body;

FIG. 8A is a perspective view of a panel body as viewed from a first surface side;

FIG. 8B is a perspective view of the panel body as viewed from a second surface side;

FIG. 8C is a top view of the panel body;

FIG. 9A is a perspective view of a panel body as viewed from a first surface side;

FIG. 9B is a perspective view of the panel body as viewed from a second surface side;

FIG. 9C is a top view of the panel body;

FIG. 9D is an enlarged cross-sectional view of a bent portion of a plate-shaped member;

FIG. 10A is a perspective view of a panel body as viewed from a first surface side;

FIG. 10B is a perspective view of the panel body as viewed from a second surface side;

FIG. 10C is a top view of the panel body;

FIG. 10D is an enlarged cross-sectional view of a bent portion of a plate-shaped member;

FIG. 11 is a schematic view illustrating an example of an overall configuration of a display device;

FIG. 12 is a schematic view illustrating the display device disassembled for parts constituting the display device;

FIG. 13A is a perspective view of a display device according to an embodiment;

FIG. 13B is a partially enlarged view of the display device according to the embodiment;

FIG. 14A is a perspective view of a display device according to an embodiment;

FIG. 14B is a partially enlarged view of the display device according to the embodiment;

FIG. 15A is a perspective view of a display device according to an embodiment;

FIG. 15B is a partially enlarged view of the display device according to the embodiment;

FIG. 16A is a perspective view of a display device according to an embodiment;

FIG. 16B is a partially enlarged view of the display device according to the embodiment;

FIG. 17A is a cross-sectional perspective view of a display device according to an embodiment;

FIG. 17B is a partially enlarged cross-sectional view of the display device according to the embodiment;

FIG. 18A is a perspective view of a display device according to an embodiment;

FIG. 18B is a partially enlarged view of the display device according to the embodiment; and

FIG. 19 is a schematic view of a display device according to an embodiment.

### DETAILED DESCRIPTION

Hereinafter, embodiments of panel bodies according to the present disclosure will be described with reference to the drawings.

### First Embodiment

### Example of Configuration of Panel Body

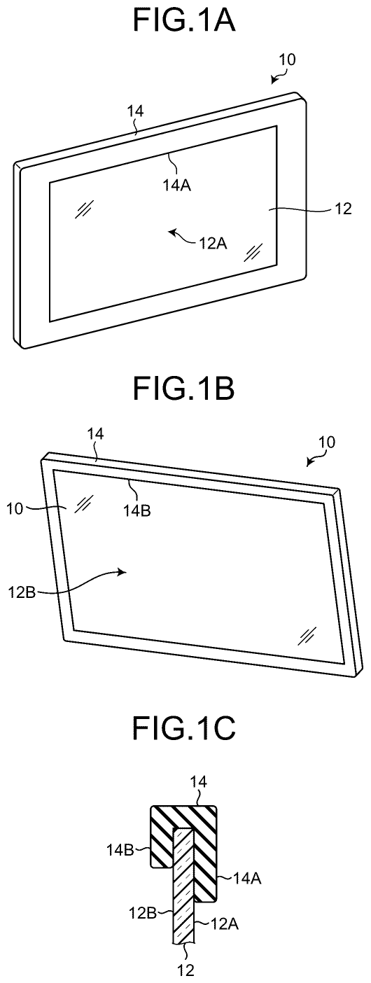

FIGS. 1A to 1C are schematic views illustrating an example of a configuration of a panel body 10 according to an embodiment. FIG. 1A is a perspective view of the panel body 10 as viewed from a first surface side, and FIG. 1B is a perspective view of the panel body 10 as viewed from a second surface side. FIG. 1C is a partially enlarged cross-sectional view of the panel body 10.

The panel body 10 includes a plate-shaped member 12 and a frame body 14.

The plate-shaped member 12 is a substantially flat plate-shaped member. The plate-shaped member 12 is made of glass, stone, wood, paper, cloth, or the like. The glass is, for example, optical glass. The optical glass is glass subjected to optical processing to have characteristics suitable for use as an optical element of a display device, such as low dependency of transmittance on wavelength and high refractive index. The present embodiment will be described, assuming that the plate-shaped member 12 is plate-shaped glass made of glass. However, the material of the plate-shaped member 12 is not limited to glass as described above.

Due to the characteristics of the frame body 14 to be described later, the plate-shaped member 12 can have a thickness of, for example, 3 mm or less. The plate-shaped member 12 may have a thickness of 1.2 mm or more and 1.5 mm or less, or may have a thickness of 0.8 mm or less.

The plate-shaped member 12 having such a small thickness is easily damaged, and needs to be carefully treated. In the panel body 10 of the embodiment, as will be described below, the frame body 14 is integrally provided around the plate-shaped member 12 to protect the plate-shaped member 12.

The frame body 14 is, for example, a resin member made of carbon fiber-reinforced resin (CFRTP: Carbon Fiber Reinforced Thermo Plastics). The CFRTP is a fiber reinforced plastic that uses carbon fiber (CF) as a reinforcing material in a base material of thermoplastic resin. By using the thermoplastic resin, which has a wide lineup of products, as the base material, it is possible to select a resin having desired characteristics from among the wide lineup of products and use the selected resin in the CFRTP.

The frame body 14 included in the panel body 10 of the embodiment is highly flame retardant, and has a thermal shrinkage characteristic close to that of the plate-shaped member 12. In addition, as compared to magnesium die-cast products, which are often used to protect glass, the frame body 14 has a lower specific gravity by about 30%, while having an approximately equal strength.

The frame body 14 is integrally molded with the plate-shaped member 12, and covers an end surface of the plate-shaped member 12 without discontinuity. That is, the frame body 14 is integrally molded with the plate-shaped member 12 to continuously cover the end surface of the plate-shaped member 12 without discontinuity, and does not have an introduction groove, a fitting groove, or the like for fitting the plate-shaped member 12 thereinto.

The frame body 14 is preferably configured to sandwich the plate-shaped member 12 from front and back surfaces thereof.

Specifically, as illustrated in FIG. 1C, for example, the frame body 14 includes a frame-shaped first pressing portion 14A extending from the end surface of the plate-shaped member 12 toward the first surface 12A, and a frame-shaped second pressing portion 14B extending from the end surface of the plate-shaped member 12 toward the second surface 12B.

The first pressing portion 14A may surround an edge portion of the first surface 12A of the plate-shaped member 12 in a frame shape, and extend longer in a direction toward the center of the plate-shaped member 12 than the second pressing portion 14B surrounding an edge portion of the second surface 12B of the plate-shaped member 12 in a frame shape.

As described above, the frame body 14 seamlessly surrounds the periphery of the plate-shaped member 12, and does not have, for example, an introduction groove or a fitting groove into which the plate-shaped member 12 is fitted. The frame body 14 having no seam or the like is also excellent in designability, and can be directly applied to a display device or the like without performing, for example, surface coating or the like thereon.

In addition, since the frame body 14 is integrally molded around the plate-shaped member 12, the torsional rigidity of the entire panel body 10 is improved. This suppresses, for example, the diagonal twisting of the rectangular plate-shaped member 12, making it easy to assemble the rectangular plate-shaped member 12 to a display device or the like. In addition, since the end surface of the plate-shaped member 12 is protected by the frame body 14, damage such as a crack or a chip in the end surface of the plate-shaped member 12 is suppressed, and the overall strength of the plate-shaped member 12 against impact, collision, and the like is improved. This makes it easier to handle the panel body 10 when transported and when assembled. The frame body 14 may have anisotropy.

The frame body 14 having anisotropy means that the frame body 14 includes a plurality of regions in which the orientation directions of the carbon fibers contained in the carbon fiber-reinforced resin constituting the frame body 14 are different from each other. Specifically, for example, in the frame body 14, the orientation direction of the carbon fibers included in the first pressing portion 14A and the orientation direction of the carbon fibers included in the second pressing portion 14B are different from each other. In detail, for example, the orientation direction of the carbon fibers included in the first pressing portion 14A and the orientation direction of the carbon fibers included in the second pressing portion 14B are orthogonal to each other. Since the frame body 14 has anisotropy as described above, the strength of the frame body 14 can be further increased. Further, by dividing the frame body 14 into a plurality of regions and adjusting the orientation direction of the carbon fibers included in each of the regions according to the strength required by the object to which the frame body 14 is applied, it is possible to provide the frame body 14 having the strength required by the object to which the frame body 14 is applied. The anisotropy of the frame body 14 can be realized by adjusting the filling direction of the carbon fiber-reinforced resin during manufacturing. A method for manufacturing the panel body 10 including the frame body 14 will be described later.

In addition, the frame body 14 may be at least partially colored. In addition, the frame body 14 may include a plurality of regions colored in different colors. For example, it is possible to form the frame body 14 colored in a plurality of colors by making the colors of the carbon fiber-reinforced resin filled in the respective regions different during manufacturing. A method for manufacturing the panel body 10 including the frame body 14 will be described later.

### Method for Manufacturing Panel Body

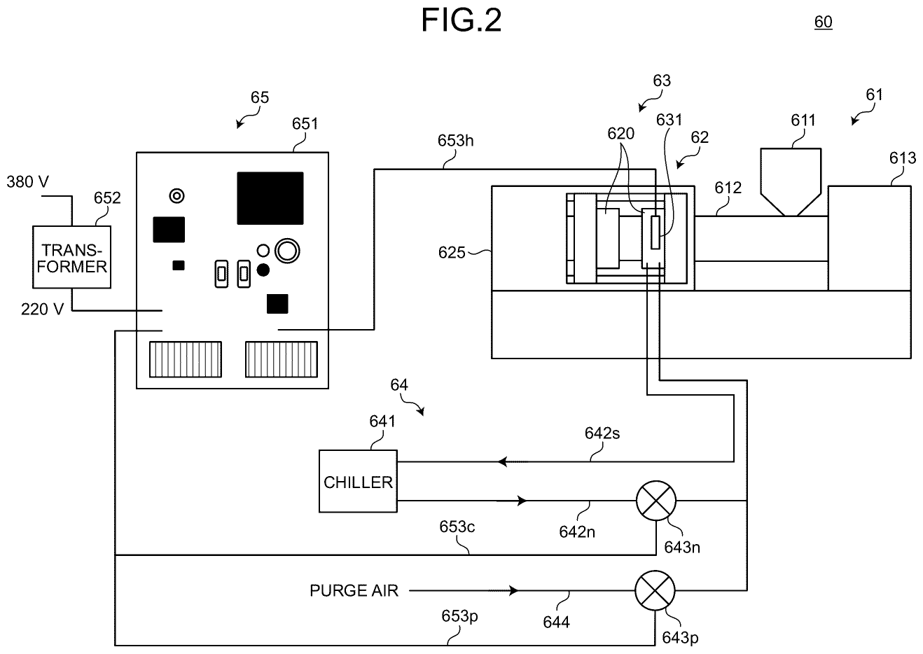

Next, a method for manufacturing the panel body 10 of the embodiment will be described with reference to FIGS. 2 to 6.

FIG. 2 is a schematic view illustrating an example of a configuration of a molding apparatus 60 used for manufacturing the panel body 10 according to the embodiment. The molding apparatus 60 of the embodiment is configured as, for example, a heat-and-cool injection molding apparatus using heater heating and water cooling.

As illustrated in FIG. 2, the molding apparatus 60 includes an injection unit 61, a mold clamping unit 62, a heating unit 63, a cooling unit 64, and a control unit 65.

The injection unit 61 includes a hopper 611, a cylinder 612, and a motor 613, and injects a resin material such as CFRTP. The hopper 611 is an inlet for the resin material. The cylinder 612 heats the carbon fiber-reinforced resin material by a heater (not illustrated) or the like, and injects the melted carbon fiber-reinforced resin material by the motor 613 connected to the cylinder 612.

The mold clamping unit 62 includes a mold 620 and a mold clamping plate 625, and molds the injected carbon fiber-reinforced resin material. The mold 620 has a cavity imitating a shape of a molded article, and is attached to the movable mold clamping plate 625. The mold 620 divided into a plurality of parts is opened and closed by the mold clamping plate 625, so that the carbon fiber-reinforced resin material filled in the cavity of the mold 620 is molded.

The heating unit 63 includes a heater 631, and heats the carbon fiber-reinforced resin material in the mold 620. The heater 631 is built in the mold 620, for example, and heats the carbon fiber-reinforced resin material filled in the cavity of the mold 620.

The cooling unit 64 includes a chiller 641, water-cooling hoses 642n and 642s, electromagnetic valves 643n and 643p, and an air pipe 644, and cools the carbon fiber-reinforced resin material in the mold 620.

The chiller 641 controls a refrigerant such as cooling water to a predetermined temperature, and circulates the refrigerant into the mold clamping unit 62 via the water-cooling hoses 642n and 642s by a pump or the like (not illustrated).

One end of each of the water-cooling hoses 642n and 642s is connected to the chiller 641, and the other end of each of the water-cooling hoses 642n and 642s is connected to a flow path (not illustrated) provided in the mold 620. The refrigerant whose temperature has been controlled by the chiller 641 is sent from the water-cooling hose 642n to the mold 620, and returned from the water-cooling hose 642s to the chiller 641.

The electromagnetic valve 643n is provided in the water-cooling hose 642n. While the mold 620 is heated by the heater 631, the electromagnetic valve 643n is closed to stop the circulation of the refrigerant into the mold 620.

One end of the air pipe 644 is connected to a supply source (not illustrated) of purge air, and the other end of the air pipe 644 is connected to a side downstream of the electromagnetic valve 643n of the water-cooling hose 642n. The electromagnetic valve 643p is provided in the air pipe 644. When the electromagnetic valve 643p is opened as necessary, purge air is supplied to the water-cooling hoses 642n and 642s and the flow path of the mold 620 through the air pipe 644, and the refrigerant in the water-cooling hoses 642n and 642s and the flow path of the mold 620 is discharged.

The control unit 65 includes a controller 651 and a transformer 652, and controls the entire molding apparatus 60.

The controller 651 is configured as a computer including, for example, a central processing unit (CPU), a read only memory (ROM), a random access memory (RAM), etc.

The controller 651 is connected to the heater 631 by a cable 653h, and controls the heating temperature, the heating time, and the like of the carbon fiber-reinforced resin material by turning on/off the heater 631. The controller 651 is connected to the electromagnetic valve 643n provided in the water-cooling hose 642n by a cable 653c, and starts or stops the supply of the refrigerant to the mold 620 by opening or closing the electromagnetic valve 643n to control the cooling temperature, the cooling time, and the like of the carbon fiber-reinforced resin material.

The controller 651 is connected to the electromagnetic valve 643p provided in the air pipe 644 by a cable 653p, and discharges the refrigerant in the water-cooling hoses 642n and 642s and the mold 620 by opening the electromagnetic valve 643p. In addition, the controller 651 may be connected to the injection unit 61, the mold clamping unit 62, and the chiller 641 by cables (not illustrated), and may be configured to control these units.

The transformer 652 steps down power supplied from a power supply (not illustrated) on the equipment side to an operating voltage of the controller 651 and supplies the operating voltage to the controller 651. When the voltage of the power from the power supply is, for example, 380 V, the transformer 652 can step it down to, for example, 220 V.

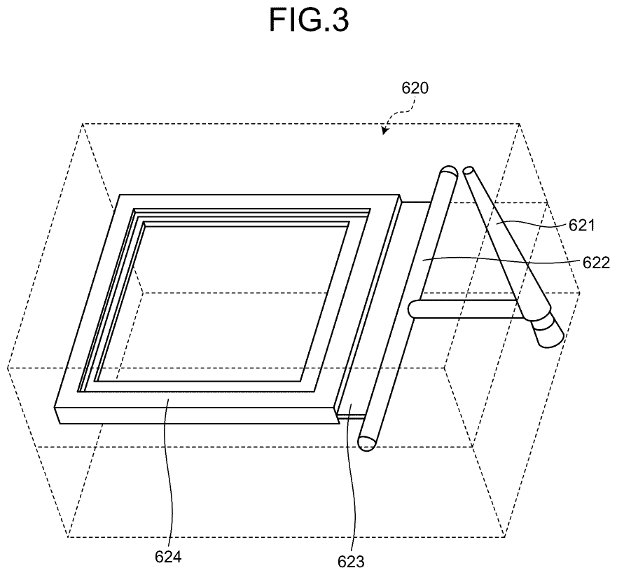

Next, a detailed configuration of the mold 620 will be described with reference to FIG. 3.

FIG. 3 is a perspective view illustrating an example of an internal structure of the mold 620 used for manufacturing the panel body 10 according to the embodiment. As illustrated in FIG. 3, the mold 620 includes a spool 621, a runner 622, a gate 623, and a cavity 624 inside.

The spool 621 is connected to a nozzle (not illustrated) at the tip of the cylinder 612 of the injection unit 61, and serves as a path for introducing the carbon fiber-reinforced resin material injected from the cylinder 612. The runner 622 is a branch path for branching the carbon fiber-reinforced resin material introduced from the spool 621 in a plurality of directions. In the example of FIG. 3, the runner 622 is provided, for example, along one side of the frame-shaped cavity 624, and extends the carbon fiber-reinforced resin material 13 in the width direction of the one side.

The gate 623 connects the runner 622 and the cavity 624, and serves as a port for filling the cavity 624 with the carbon fiber-reinforced resin material. In the example of FIG. 3, the gate 623 is also provided along the one side of the frame-shaped cavity 624 to allow the carbon fiber-reinforced resin material to flow into the cavity 624, for example, from the entire width of the one side. The film-shaped gate 623 connecting the runner 622 along the molded article as described above is also referred to as, for example, a film gate.

The film gate allows the carbon fiber-reinforced resin material to uniformly flow into the cavity, and is excellent in filling the carbon fiber-reinforced resin material. Therefore, the film gate is suitably used for forming a thin and wide molded article such as the frame body 14 of the embodiment.

As described above, the cavity 624 is configured in a frame shape imitating the shape of the frame body 14, for example, which is a molded article. The plate-shaped member 12 can be accommodated inside the frame of the cavity 624. The frame body 14 integrally molded with the plate-shaped member 12 is formed by filling the carbon fiber-reinforced resin material in a state where the plate-shaped member 12 is accommodated in the cavity 624 in advance.

As described above, since the cavity 624 is formed to accommodate the plate-shaped member 12, it is possible to perform insert molding in which different materials, a material such as glass or cloth constituting the plate-shaped member 12 and a carbon fiber-reinforced resin material constituting the frame body 14, are integrally molded.

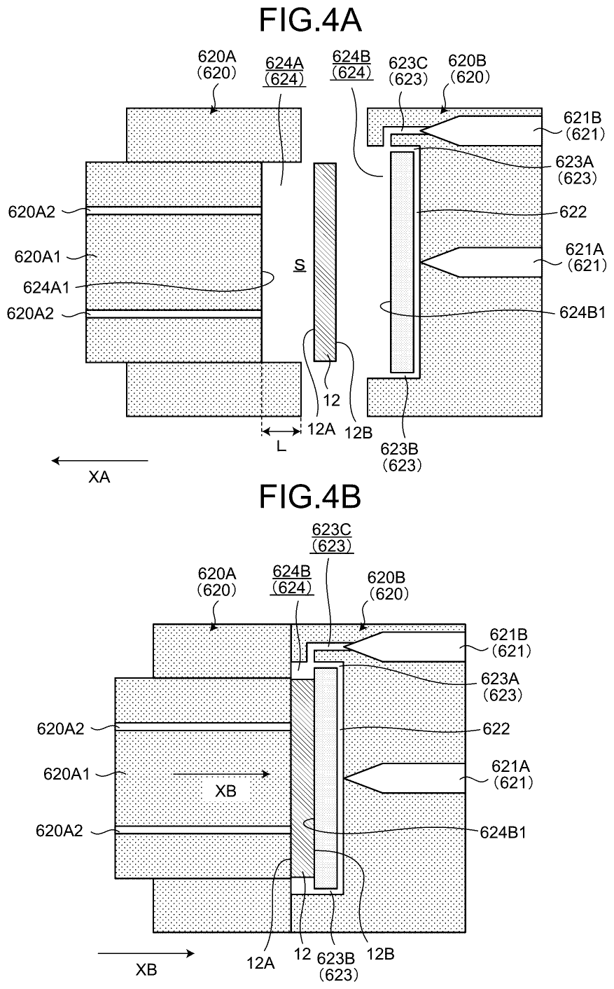

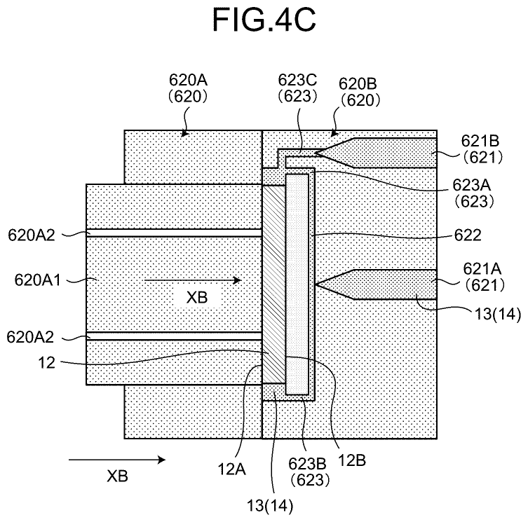

Next, a method for manufacturing the panel body 10 will be described in detail with reference to FIGS. 4A to 4C.

FIGS. 4A to 4C are views for explaining an example of a method for manufacturing the panel body 10.

The method for manufacturing the panel body 10 includes an inserting step, a heating step, a sliding step, a filling step, and a cooling step.

FIG. 4A is a view for explaining an example of the inserting step.

Specifically, the mold 620 includes a first mold 620A and a second mold 620B.

The first mold 620A includes a slide portion 620A1.

The slide portion 620A1 is configured to be slidable with respect to the main body of the first mold 620A in both a direction approaching the second mold 620B and a direction away from the second mold 620B. In the inserting step, the slide portion 620A1 is temporarily fixed in a state where it is slid in a direction (a direction indicated by arrow XA) away from the second mold 620B disposed opposite to the slide portion 620A1. By being temporarily fixed at this position, a first recessed portion 624A is formed in the first mold 620A. The first recessed portion 624A constitutes a part of the cavity, and a depth L of the first recessed portion 624A is adjusted in advance so as to be deeper than a thickness of the plate-shaped member 12 that constitutes the panel body 10.

The slide portion 620A1 has one or a plurality of suction holes 620A2. The suction hole 620A2 is a through hole that enable communication between a space in the first recessed portion 624A and a space outside the first mold 620A, and is a hole for sucking air in the first recessed portion 624A in a direction away from the second mold 620B (a direction indicated by arrow XA).

The second mold 620B is a mold having a second recessed portion 624B disposed opposite to the first recessed portion 624A, and constitutes one mold 620 together with the first mold 620A. A space S formed by the first recessed portion 624A and the second recessed portion 624B functions as a cavity 624 for forming the frame body 14 when the first mold 620A and the second mold 620B are closed by the mold clamping plate 625 in a state where the plate-shaped member 12 is inserted into the space S.

The second mold 620B includes a spool 621, a runner 622, and a gate 623. For example, the second mold 620B may include a plurality of spools 621 such as a spool 621A and a spool 621B. In addition, the second mold 620B may include a plurality of gates 623 such as a gate 623A, a gate 623B, and a gate 623C whose filling locations are different from each other.

The plurality of gates 623 provided in the mold 620 may be provided in advance in the mold 620, and any gate 623 may be configured to selectively function as a port for filling the carbon fiber-reinforced resin material by opening/closing control of the controller 651 or the like. In addition, a new gate 623 may be formed by sliding some of the parts constituting the mold 620, and any gate 623 may be configured to selectively function as a port for filling the carbon fiber-reinforced resin material.

In the inserting step, the plate-shaped member 12 is inserted into the space S formed by the first recessed portion 624A of the first mold 620A and the second recessed portion 624B of the second mold 620B in a state where the first mold 620A and the second mold 620B are spaced apart from each other in a direction away from each other. A known insertion device may be used to insert the plate-shaped member 12. Then, air in the first recessed portion 624A is sucked from the suction holes 620A2 to the outside of the first mold 620A in the direction indicated by arrow XA using a suction mechanism, so that the first surface 12A of the plate-shaped member 12 is adsorbed to a bottom portion 624A1 of the first recessed portion 624A and is disposed in contact with the bottom portion 624A1.

Next, in the heating step, the first mold 620A and the second mold 620B are closed by the mold clamping plate 625 in a state where the plate-shaped member 12 is sandwiched in the space S between the first mold 620A and the second mold 620B. As a result, at least one of the first mold 620A and the second mold 620B is pressed to approach each other. Then, the heating unit 63 heats the mold 620 to a temperature equal to or higher than the temperature at which the plate-shaped member 12 can be molded and the melting temperature of the carbon fiber-reinforced resin material. By heating the mold 620, the plate-shaped member 12 sandwiched in the mold 620 is heated to the temperature to become in a state where its shape can be adjusted.

In the sliding step, the bottom portion 624A1 of the first recessed portion 624A of the first mold 620A is slid toward a bottom portion 624B1 of the second recessed portion 624B opposite to the first recessed portion 624A until the second surface 12B of the plate-shaped member 12 comes into contact with the bottom surface of the bottom portion 624B1.

FIG. 4B is a view for explaining an example of the sliding step. The sliding step is performed in a state where the first mold 620A and the second mold 620B are closed with the plate-shaped member 12 sandwiched therebetween, and the mold 620 is heated by the heating step. In the sliding step, the slide portion 620A1 is slid in a direction indicated by arrow XB toward the bottom portion 624B1 of the second recessed portion 624B, and is slid until the second surface 12B of the plate-shaped member 12 comes into contact with the bottom surface of the bottom portion 624B1 of the second recessed portion 624B. At this time, the slide portion 620A1 compresses the plate-shaped member 12 in a heated state between the bottom surface of the bottom portion 624A1 of the slide portion 620A1 and the bottom surface of the bottom portion 624B1 of the second recessed portion 624B, thereby pressing and compressing the plate-shaped member 12 toward the bottom surface of the bottom portion 624B1 with a pressure to such an extent that the plate-shaped member 12 is molded into a target shape.

Therefore, even if there is a variation in shape between a plurality of plate-shaped members 12 due to manufacturing conditions, storage conditions, and the like, the plate-shaped members 12 are molded into a target shape, and the variation in shape is suppressed.

Furthermore, by adjusting the heating temperature in the heating step and the pressed/compressed degree of the plate-shaped member 12 in the sliding step according to the material of the plate-shaped member 12, the plate-shaped member 12 can be adjusted to a target shape regardless of the material of the plate-shaped member 12.

In addition, as described above, the first recessed portion 624A constitutes a part of the cavity, and the depth L of the first recessed portion 624A is adjusted in advance so as to be deeper than the thickness of the plate-shaped member 12 that constitutes the panel body 10. Therefore, it is possible to absorb a variation in shape such as degree of shape distortion between the plate-shaped members 12 before being inserted, a difference in degree of sitting on the mold 620 caused by a difference in weight of material between the plate-shaped member 12, a variation in easiness in fixation to the mold 620, and the like, so that the plate-shaped member 12 can be pressed and compressed against the bottom surface of the second recessed portion 624B in a state where the plate-shaped member 12 is stably held in the first recessed portion 624A.

FIG. 4C is a view for explaining an example of the filling step. In the filling step, in the space S between the first mold 620A and the second mold 620B in the closed state in the above-described step, the carbon fiber-reinforced resin material 13 is filled in a space that is a gap between the plate-shaped member 12 and the mold 620 and covers the end surface of the plate-shaped member 12.

In the filling step, the space (cavity) is filled with the carbon fiber-reinforced resin material 13 from the spool 621 connected to a nozzle (not illustrated) at the tip of the cylinder 612 of the injection unit 61 via the runner 622 and the gate 623.

In the cooling step, the heating performed by the heating unit 63 is stopped, and the mold 620 is cooled by the cooling unit 64. By cooling the mold 620, the panel body 10 in which different materials, the material such as glass constituting the plate-shaped member 12 and the carbon fiber-reinforced resin material 13 constituting the frame body 14, are integrally molded is manufactured.

As described above, the method for manufacturing the panel body 10 of the present embodiment includes an inserting step, a heating step, a sliding step, a filling step, and a cooling step. Therefore, in the method for manufacturing the panel body 10 of the present embodiment, it is possible to perform insert molding in which different materials, a material such as glass or cloth constituting the plate-shaped member 12 and a carbon fiber-reinforced resin material 13 constituting the frame body 14, are integrally molded.

In the filling step, the carbon fiber-reinforced resin material 13 may be filled such that the frame body 14 has anisotropy. In the filling step, the carbon fiber-reinforced resin material 13 may be filled such that the frame body 14 is at least partially colored.

As described above, the second mold 620B includes a spool 621, a runner 622, and a gate 623. For example, the second mold 620B may include a plurality of spools 621 such as a spool 621A and a spool 621B. In addition, the second mold 620B may include a plurality of gates 623 such as a gate 623A, a gate 623B, and a gate 623C whose filling locations are different from each other. The gate 623, the gate 623A, the gate 623B, and the gate 623C are examples of ports for filling the carbon fiber-reinforced resin material 13. The plurality of gates 623 are different from each other in position at which it is started to fill the carbon fiber-reinforced resin material 13 into the space S.

In the filling step, under the control of the controller 651, the cavity is filled with the carbon fiber-reinforced resin material 13 from the gate 623, which forms a flow in a filling direction such that the orientation direction of the carbon fibers is aligned in a desired direction, via the spool 621 and the runner 622 connected to a nozzle (not illustrated) at the tip of the cylinder 612 of the injection unit 61. Therefore, by selecting and switching the gate 623 to be filled with the carbon fiber-reinforced resin material 13 under the control of the controller 651, the carbon fiber-reinforced resin material 13 is filled in the cavity for the frame body 14 such that the orientation direction of the carbon fibers contained therein becomes a desired direction. Therefore, the frame body 14 can include a plurality of regions in which the orientation directions of the carbon fibers contained in the carbon fiber-reinforced resin material 13 constituting the frame body 14 are different from each other.

In the filling step, as the carbon fiber-reinforced resin material 13, carbon fiber-reinforced resin materials 13 of a plurality of colors different from each other may be prepared. Then, for each color, the controller 651 may select the gate 623 for filling a region to be colored with the color, and may perform control to fill the carbon fiber-reinforced resin material 13 of the color from the gate 623.

Therefore, the frame body 14 can include a plurality of regions colored in different colors.

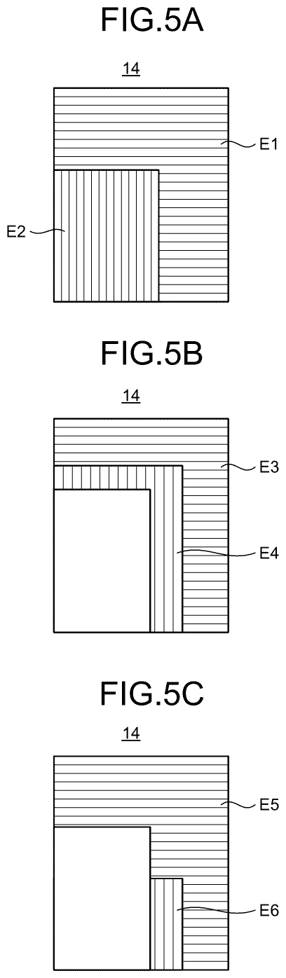

FIGS. 5A to 5C are views each for explaining an example of the frame body 14 having anisotropy and colored in a plurality of colors. FIGS. 5A to 5C illustrate enlarged views of corners of the frame body 14.

For example, as illustrated in FIG. 5A, by executing the filling step, it is possible to form a frame body 14 including a plurality of regions E1 and E2 that are different in color and carbon fiber orientation direction. In addition, as illustrated in FIG. 5B, it is also possible to form a frame body 14 including regions E3 and E4 that are different in color and carbon fiber orientation direction from those in FIG. 5A. In addition, as illustrated in FIG. 5C, it is also possible to form a frame body 14 including region E5 and region E6 that are different in color and carbon fiber orientation direction from those in FIGS. 5A and 5B.

Since the frame body 14 has anisotropy, the strength of the frame body 14 can be further increased. In addition, by dividing the frame body 14 into a plurality of regions according to the object to which the frame body 14 is applied and adjusting the orientation direction of the carbon fibers included in each of the regions according to the strength required by the object to which the frame body 14 is applied, it is possible to provide the frame body 14 having the strength required by the object to which the frame body 14 is applied.

In addition, by configuring the frame body 14 to be at least partially colored, it is possible to impart desired designability to the frame body 14.

Next, the temperature condition of the molding apparatus 60 when the frame body 14 is integrally molded with the plate-shaped member 12 will be described in detail.

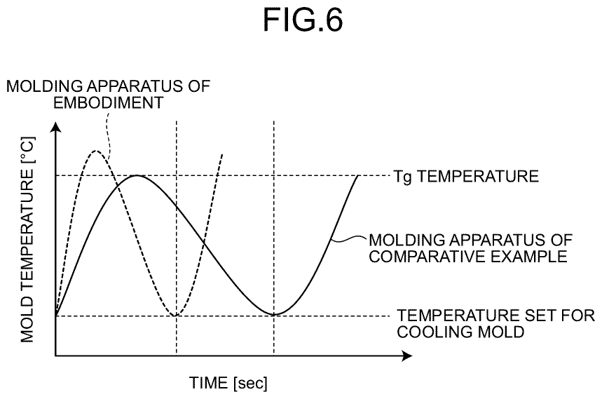

FIG. 6 is a view illustrating an example of the temperature condition of the molding apparatus 60 when the frame body 14 according to the embodiment is integrally molded with the plate-shaped member 12.

A horizontal axis of a graph illustrated in FIG. 6 represents a molding time (sec), and a vertical axis of the graph represents a temperature (° C.) of the mold 620. In addition, the graph of FIG. 6 illustrates a temperature condition in a steam heating type molding apparatus as a molding apparatus of a comparative example as well as the molding apparatus 60.

As illustrated in FIG. 6, in the molding apparatus of the comparative example, the temperature condition of the mold is changed according to the change in state of the refrigerant between high-temperature and high-pressure water vapor and cooling water, so that a certain period of time is required for the heating/cooling cycle. In addition, since steam heating is used, it is difficult to heat the mold to a temperature equal to or higher than the melting point Tg of the resin material.

On the other hand, in the molding apparatus 60 of the embodiment, heating and cooling can be quickly switched by independently controlling the heating unit 63 and the cooling unit 64, shortening the heating/cooling cycle. In addition, since heating is performed in an electrothermal manner, the heating can be controlled to a temperature higher than the melting point Tg of the carbon fiber-reinforced resin material 13.

The CFRTP used for the frame body 14 of the embodiment is a material having high strength, but difficult to mold with a small amount of deformation. By heating the CFRTP to a high temperature in the electrothermal heating manner, it is possible to control the orientation even though the CFRTP is difficult to mold, and it is possible to easily mold a thin frame body 14 to correspond to the thin plate-shaped member 12 described above.

In addition, since high-temperature heating randomizes the orientation of the CFRTP, it is possible to suppress molding defects such as weld lines, which are linear marks formed at merging portions of the molten resin, and also reduce residual stress to reduce the warpage of the molded article. This makes it possible to further enhance the strength of the frame body 14. The high-temperature heating enables high-gloss molding, making it possible to add high designability.

Furthermore, by providing multiple channels for heating/cooling in the molding apparatus 60, it is possible to perform control under different temperature conditions between a plurality of points in the cavity 624. This makes it easier to reduce the residual stress, thereby further reducing the warpage of the molded article.

As described above, the CFRTP used for the frame body 14 of the embodiment has a thermal shrinkage rate close to that of the plate-shaped member 12. Therefore, when the molded article is released from the mold 620, it is possible to suppress damage to the plate-shaped member 12 due to the thermal shrinkage of the frame body 14. This makes it possible to integrally mold the frame body 14 with the plate-shaped member 12 thinned to, for example, 3 mm or less, 1.2 mm or more and 1.5 mm or less, or 0.8 mm or less.

### Overview

As the screen size of the display device increases, it is more difficult to transport and assemble the plate-shaped member 12 made of glass or the like. In addition, the number of various display devices mounted on vehicles, such as monitors of navigation systems, is also increasing.

In a case where the display device is used as an on-vehicle device, when the display device is attached to the vehicle, slight diagonal twisting may occur in the plate-shaped member 12 made of glass or the like due to a vehicle bracket, another interior part, and the like, and in this case, there is a concern that the plate-shaped member 12 may be damaged instantaneously or over time.

On the other hand, the display device used as the in-vehicle device is also required to satisfy collision safety such as Federal Motor Vehicle Safety Standards in the United States and Regulations for Interior Fittings in Japan, Europe, and the like.

For this reason, a technique is known in which a metal-pressed product, a die-cast product, or the like is added to a glass part to enhance strength. In recent years, for example, die-cast products made of magnesium, which is lightweight and has high strength, have attracted attention. However, it takes a long tack time to manufacture a metal part made of magnesium or the like, and the production number is limited. In addition, there is also a problem that many portions are disposed of by deburring or the like, resulting in an increase in cost.

The panel body 10 of the embodiment includes a plate-shaped member 12 and a frame body 14 made of CFRTP and integrally molded with the plate-shaped member 12, and the frame body 14 covers an end surface of the plate-shaped member 12 without discontinuity.

By integrally molding the frame body 14 made of CFRTP with the plate-shaped member 12 as described above, the panel body 10 having high strength can be obtained. In addition, the torsional rigidity of the entire plate-shaped member 12 can be improved. Therefore, a crack or a chip of the plate-shaped member 12 can be suppressed, making it easy to handle the plate-shaped member 12.

In addition, since the frame body 14 covers the end surface of the plate-shaped member 12 without discontinuity, designability can be added to the panel body 10, and it is also possible to directly apply the frame body 14 to the display device or the like without performing, for example, surface coating or the like thereon.

In addition, by using the frame body 14 made of CFRTP as an alternative to a metal part such as a magnesium die-cast product, it is possible to further reduce the weight while maintaining the strength.

In addition, by using CFRTP having thermal

shrinkage close to that of the plate-shaped member 12 for the frame body 14, it is possible to suppress damage to the plate-shaped member 12 due to the thermal shrinkage of the frame body 14 at the time of release from the mold 620.

According to the panel body 10 of the embodiment, the frame body 14 is configured to sandwich the plate-shaped member 12 from front and back surfaces thereof. That is, the frame body 14 includes a first pressing portion 14A that extends from the end surface of the plate-shaped member 12 toward the first surface 12A and surrounds the edge portion of the first surface 12A in a frame shape, and a second pressing portion 14B that extends from the end surface of the plate-shaped member 12 toward the second surface 12B and surrounds the edge portion of the second surface 12B in a frame shape.

In this manner, the end surface of the plate-shaped member 12 can be more reliably protected by the first pressing portion 14A holding the first surface 12A of the plate-shaped member 12, thereby further enhancing the strength of the panel body 10. In addition, since the frame body 14 holds the plate-shaped member 12 from front and back surfaces thereof, the strength of the plate-shaped member 12 can be uniformly enhanced. Therefore, even if the plate-shaped member 12 made of glass or the like cracks due to impact, collision, or the like, the plate-shaped member 12 is less likely to scatter. In general, glass scatters due to uneven strength.

According to the panel body 10 of the embodiment, the plate-shaped member 12 has a thickness of 3 mm or less, 1.2 mm or more and 1.5 mm or less, or 0.8 mm or less. By providing the frame body 14 as described above on the plate-shaped member 12, it is possible to suppress a crack or a chip even though the plate-shaped member 12 is thinned as described above, making it easy to handle the plate-shaped member 12. Further, it is possible to suppress damage to the plate-shaped member 12 due to the thermal shrinkage of the frame body 14 at the time of mold release.

According to the method for manufacturing the panel body 10 of the embodiment, the frame body 14 is molded at a temperature exceeding the melting point Tg by heat and cool molding. A film gate is used as the gate 623 of the mold 620.

This makes it possible to form the frame body 14 using CFRTP, which is a material that is difficult to mold. In addition, the orientation of the CFRTP can be controlled to form a thin frame body 14. In addition, the orientation of the CFRTP becomes random, making it possible to suppress molding defects such as weld lines to further enhance the strength of the frame body 14. In addition, the residual stress can be reduced to reduce the warpage of the frame body 14. Therefore, the plate-shaped member 12 can be thinned. In addition, the surface of the frame body 14 becomes highly glossy, making it possible to further impart designability.

### First Modification

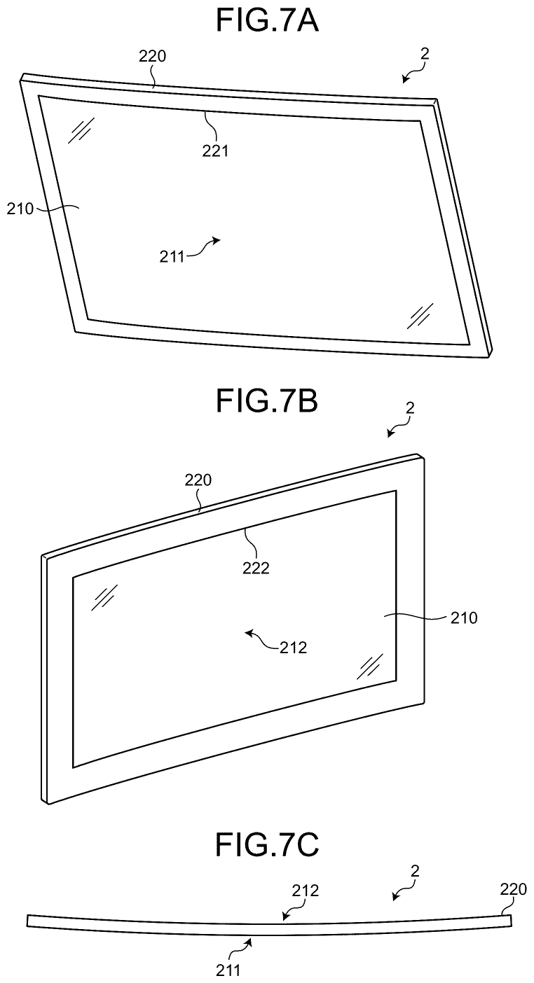

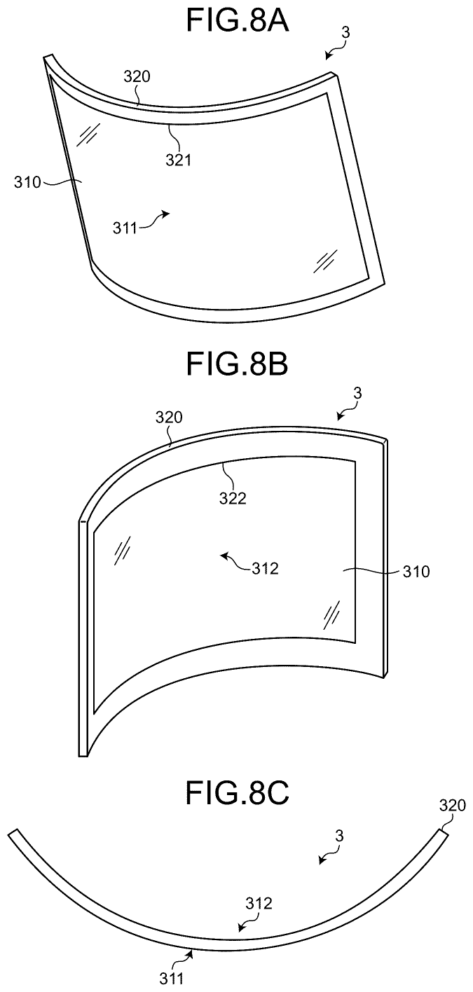

Next, panel bodies 2 and 3 according to the first modification of the embodiment will be described with reference to FIGS. 7A to 8C. The panel bodies 2 and 3 of the first modification are different from the panel body 10 of the above-described embodiment in that the panel bodies 2 and 3 include curved plate-shaped members 210 and 310. In FIGS. 7A to 8C, the components that are the same as those of the panel body 10 of the above-described embodiment are denoted by the same reference numerals, and the description thereof will be omitted.

FIGS. 7A to 7C are schematic views illustrating an example of a configuration of the panel body 2 according to the first modification of the embodiment. FIG. 7A is a perspective view of the panel body 2 as viewed from a first surface side, FIG. 7B is a perspective view of the panel body 2 as viewed from a second surface side, and FIG. 7C is a top view of the panel body 2.

As illustrated in FIGS. 7A to 7C, the panel body 2 includes a plate-shaped member 210 and a frame body 220.

The plate-shaped member 210 is a rectangular optical glass having a curved surface. The curved surface of the plate-shaped member 210 may have, for example, a substantially uniform curvature. At this time, in the example of FIGS. 7A to 7C, a first surface 211 of the plate-shaped member 210 is a convex surface, and a second surface 212 of the plate-shaped member 210 is a concave surface. Note that FIGS. 7A to 7C illustrates an example in which the plate-shaped member 210 has a relatively small curvature.

The frame body 220 is a resin member made of CFRTP and integrally molded with the plate-shaped member 210, and covers an end surface of the plate-shaped member 210 without discontinuity. In addition, the frame body 220 is configured to sandwich the plate-shaped member 210 from front and back surfaces thereof, and includes a second pressing portion 14B1 as a frame-shaped first pressing portion extending from the end surface of the plate-shaped member 210 toward the first surface 211, and a frame-shaped second pressing portion 14B2 extending from the end surface of the plate-shaped member 210 toward the second surface 212.

The second pressing portion 14B1 surrounds an edge portion of the first surface 211 of the plate-shaped member 210 in a frame shape, and may have a shorter width extending in a direction toward the center of the plate-shaped member 210 than the second pressing portion 14B2 surrounding an edge portion of the second surface 212 of the plate-shaped member 210 in a frame shape.

FIGS. 8A to 8C are schematic views illustrating another example of a configuration of the panel body 3 according to a modification of the embodiment. FIG. 8A is a perspective view of the panel body 3 as viewed from a first surface side, FIG. 8B is a perspective view of the panel body 3 as viewed from a second surface side, and FIG. 8C is a top view of the panel body 3.

As illustrated in FIGS. 8A to 8C, the panel body 3 includes a plate-shaped member 310 and a frame body 320.

The plate-shaped member 310 is a rectangular optical glass having a curved surface. The curved surface of the plate-shaped member 310 may have, for example, a substantially uniform curvature. At this time, in the example of FIGS. 8A to 8C, a first surface 311 of the plate-shaped member 310 is a convex surface, and a second surface 312 of the plate-shaped member 310 is a concave surface. Note that FIGS. 8A to 8C illustrate an example in which the plate-shaped member 310 has a relatively large curvature.

The frame body 320 is a resin member made of CFRTP and integrally molded with the plate-shaped member 310, and covers an end surface of the plate-shaped member 310 without discontinuity. In addition, the frame body 320 is configured to sandwich the plate-shaped member 310 from front and back surfaces thereof, and includes a pressing portion 321 as a frame-shaped first pressing portion extending from the end surface of the plate-shaped member 310 toward the first surface 311, and a pressing portion 322 as a frame-shaped second pressing portion extending from the end surface of the plate-shaped member 310 toward the second surface 312.

The pressing portion 321 surrounds an edge portion of the first surface 311 of the plate-shaped member 310 in a frame shape, and may have a shorter width extending in a direction toward the center of the plate-shaped member 310 than the pressing portion 322 surrounding an edge portion of the second surface 312 of the plate-shaped member 310 in a frame shape.

In order to mold the frame body 220 or 320 integrally with the plate-shaped member 210 or 310 having the curved surface as described above, it is possible to use a mold capable of accommodating the curved glass.

As described above, in recent years, there has been an increasing demand for display devices to be used for various purposes such as for in-vehicle use. In addition, in accordance with the practical use of organic EL, it is expected that there will be a demand for designs using curved glass. The curved surface of the glass is thought to further complicate handling the glass part during transportation, assembly, and installation in a vehicle or the like, and the object such as suppression of twisting of the glass part during assembly and installation.

According to the panel body 2 or 3 of the first modification, the plate-shaped member 210 or 310 has a curved surface. By integrally molding the frame body 220 or 320 as described above, the plate-shaped member 210 or 310 having such a curved surface can be applied to the panel body 2 or 3.

According to the panel body 2 or 3 of the first modification, the effects that are the same as those of the panel body 10 of the above-described embodiment are obtained.

### Second Modification

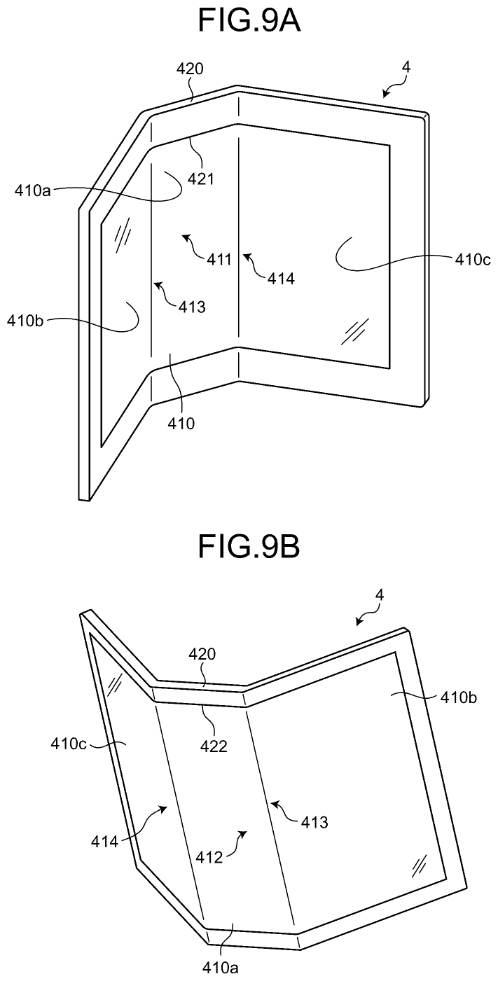

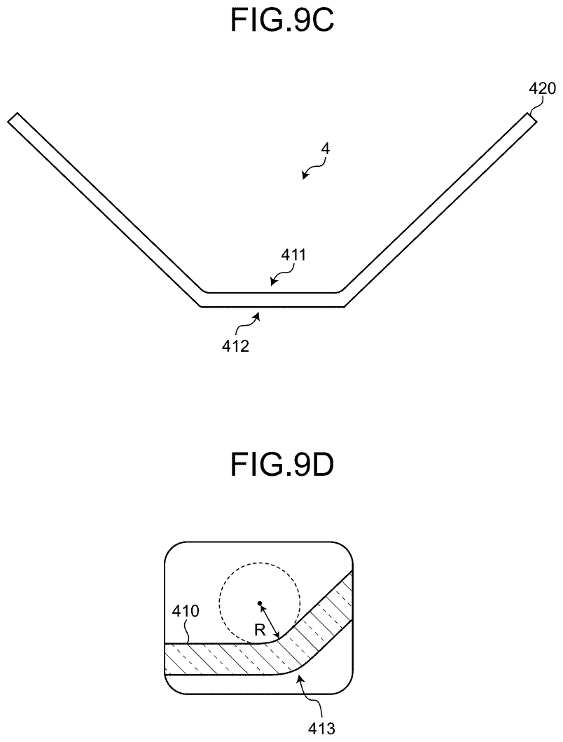

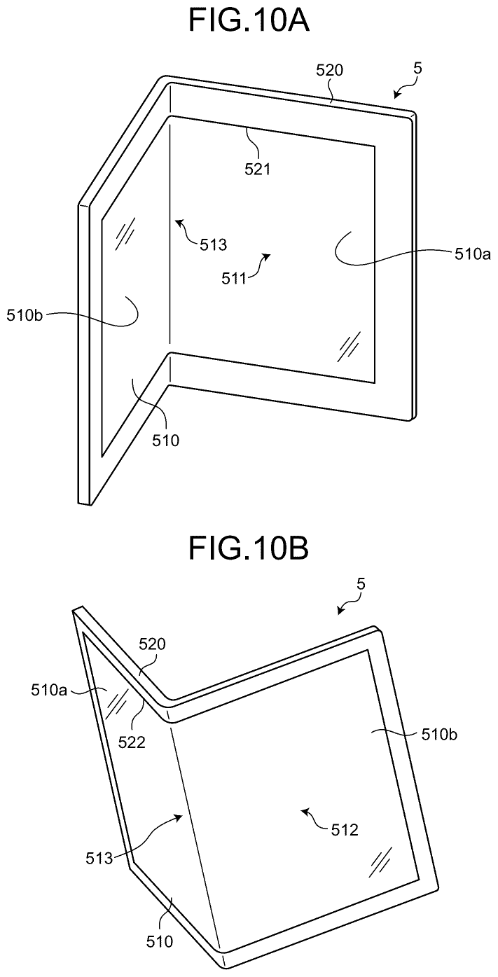

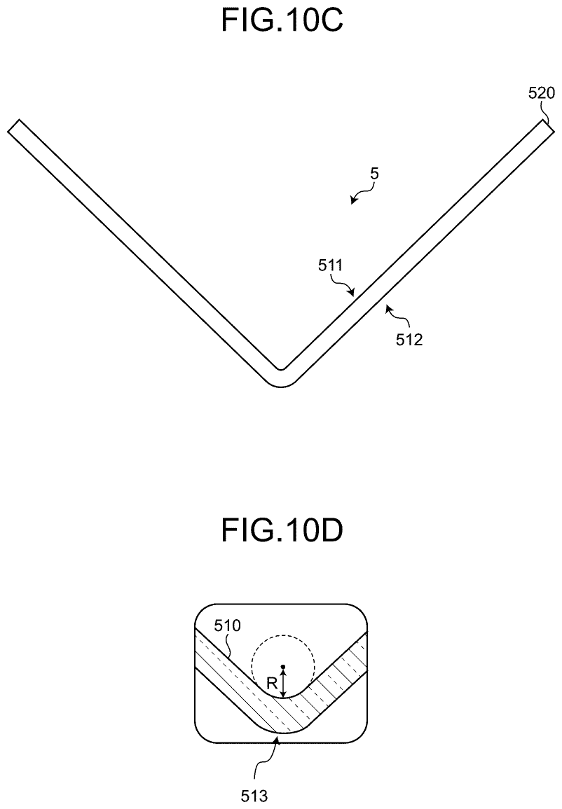

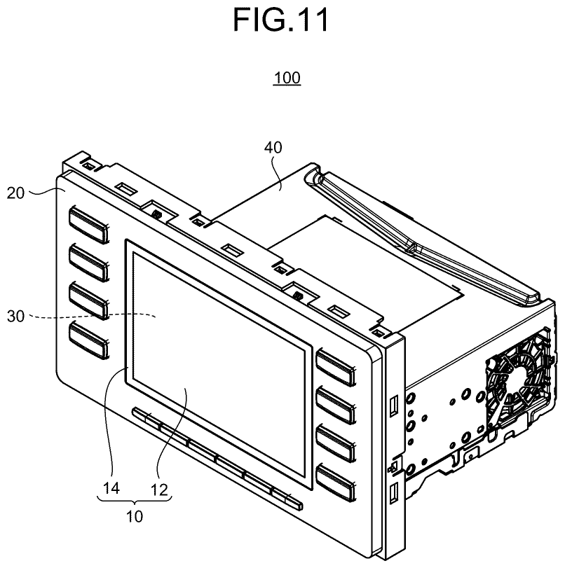

Next, panel bodies 4 and 5 of the second modification of the embodiment will be described with reference to FIGS. 9A to 10D. The panel bodies 4 and 5 of the second modification are different from the panel body 10 of the above-described embodiment in that plate-shaped members 410 and 510 are bent glasses. In FIGS. 9A to 10D, the components that are the same as those of the panel body 10 of the above-described embodiment are denoted by the same reference numerals, and the description thereof will be omitted.

FIGS. 9A to 9D are schematic views illustrating an example of a configuration of the panel body 4 according to a second modification of the embodiment. FIG. 9A is a perspective view of the panel body 4 as viewed from a first surface side, FIG. 9B is a perspective view of the panel body 4 as viewed from a second surface side, FIG. 9C is a top view of the panel body 4, and FIG. 9D is an enlarged cross-sectional view of a bent portion 413 of the plate-shaped member 410.

As illustrated in FIGS. 9A to 9D, the panel body 4 includes a plate-shaped member 410 and a frame body 420.

The plate-shaped member 410 is a bent glass obtained by bending a substantially flat rectangular optical glass at a plurality of portions. That is, the plate-shaped member 410 includes a plate-shaped portion 410a as a first surface, a plate-shaped portion 410b as a second surface adjacent to the plate-shaped portion 410a on one end side, and a plate-shaped portion 410c as a third surface adjacent to the plate-shaped portion 410a on the other end side opposite to the plate-shaped portion 410b.

The plate-shaped portion 410a and the plate-shaped portion 410b are connected to each other at a predetermined angle by a bent portion 413 as a first bent portion. The plate-shaped portion 410b and the plate-shaped portion 410c are connected to each other at a predetermined angle by a bent portion 414 as a second bent portion. At this time, in the example of FIGS. 9A to 9D, a first surface 411 of the plate-shaped member 410 is on a valley side of the bent portions 413 and 414, and a second surface 412 of the plate-shaped member 410 is on a crest side of the bent portions 413 and 414.

Note that FIGS. 9A to 9D illustrate an example in which the bent angles of the bent portions 413 and 414 are obtuse angles. In the example of FIGS. 9A to 9D, the angle formed by the plate-shaped portion 410a and the plate-shaped portion 410b and the angle formed by the plate-shaped portion 410b and the plate-shaped portion 410c are, for example, 135°. However, these angles may be different from each other.

Such bent portions 413 and 414 have minute curved surfaces. That is, since the bent portions 413 and 414 have minute curved surfaces, the plate-shaped portions 410a to 410c are connected to one another at a predetermined angle. In this case, the local curvature at each of the bent portions 413 and 414 is larger than the curvature of each of the plate-shaped members 210 and 310, which are generally curved, of the above-described first modification.

As illustrated in FIG. 9D, when the curvature at the bent portion 413 is represented by a bending radius (bending R) that is a distance from a bent position of the plate-shaped member 410 to the center point of the bending, the bending R of the plate-shaped member 410 at the bent portion 413 can be, for example, 5 mm or less.

In the example of FIGS. 9A to 9D, the plate-shaped portion 410b and the plate-shaped portion 410c are equal in size, and the plate-shaped portion 410a is smaller in size than the plate-shaped portions 410b and 410c. However, the sizes of these plate-shaped portions 410a to 410c can be changed in various ways depending on the design or the like of the display device to be assembled.

The frame body 420 is a resin member made of CFRTP and integrally molded with the plate-shaped member 410, and covers an end surface of the plate-shaped member 410 without discontinuity. The frame body 420 is configured to sandwich the plate-shaped member 410 from front and back surfaces thereof, and includes a pressing portion 421 as a frame-shaped first pressing portion extending from the end surface of the plate-shaped member 410 toward the first surface 411, and a pressing portion 422 as a frame-shaped second pressing portion extending from the end surface of the plate-shaped member 410 toward the second surface 412.

The pressing portion 421 surrounds an edge portion of the first surface 411 of the plate-shaped member 410 in a frame shape, and may extend longer in a direction toward the center of the plate-shaped member 410 than the pressing portion 422 surrounding an edge portion of the second surface 412 of the plate-shaped member 410 in a frame shape.

FIGS. 10A to 10D are schematic views illustrating another example of a configuration of the panel body 5 according to the second modification of the embodiment. FIG. 10A is a perspective view of the panel body 5 as viewed from a first surface side, FIG. 10B is a perspective view of the panel body 5 as viewed from a second surface side, FIG. 10C is a top view of the panel body 5, and FIG. 10D is an enlarged cross-sectional view of a bent portion 513 of the plate-shaped member 510.

As illustrated in FIGS. 10A to 10D, the panel body 5 includes a plate-shaped member 510 and a frame body 520.

The plate-shaped member 510 is a bent glass obtained by bending a substantially flat rectangular optical glass at one position. That is, the plate-shaped member 510 includes a plate-shaped portion 510a as a first surface and a plate-shaped portion 510b as a second surface adjacent to the plate-shaped portion 510a on one end side.

The plate-shaped portion 510a and the plate-shaped portion 510b are connected to each other at a predetermined angle by a bent portion 513 as a first bent portion. At this time, in the example of FIGS. 10A to 10D, a first surface 511 of the plate-shaped member 510 is on a valley side of the bent portion 513, and a second surface 512 of the plate-shaped member 510 is on a crest side of the bent portion 513.

Note that FIGS. 10A to 10D illustrate an example in which the bent angle of the bent portion 513 is a smaller angle. In the example of FIGS. 10A to 10D, the angle formed by the plate-shaped portion 510a and the plate-shaped portion 510b is, for example, 92°. In this manner, the frame body 520 can also be applied to, for example, a bent glass having an angle of less than 95° close to the right angle.

Such a bent portion 513 also has a minute curved surface. That is, since the bent portion 513 has a minute curved surface, the plate-shaped portion 510a and the plate-shaped portion 510b are connected to each other at a predetermined angle. In this case, the local curvature at the bent portion 513 is further larger than the curvature of each of the bent portions 413 and 414 of the plate-shaped member 410 described above.

As illustrated in FIG. 10D, when the curvature at the bent portion 513 is represented by the above-described bending radius (bending R), the bending R can be, for example, less than 1.5 mm when the bent angle of the plate-shaped member 510 is less than 95°. As in the example of FIG. 10, when the bent angle of the plate-shaped member 510 is 92°, the bending R can be, for example, 1 mm.

The frame body 520 is a resin member made of CFRTP and integrally molded with the plate-shaped member 510, and covers an end surface of the plate-shaped member 510 without discontinuity. The frame body 520 is configured to sandwich the plate-shaped member 510 from front and back surfaces thereof, and includes a pressing portion 521 as a frame-shaped first pressing portion extending from the end surface of the plate-shaped member 510 toward the first surface 511, and a pressing portion 522 as a frame-shaped second pressing portion extending from the end surface of the plate-shaped member 510 toward the second surface 512.

The pressing portion 521 surrounds an edge portion of the first surface 511 of the plate-shaped member 510 in a frame shape, and may extend longer in a direction toward the center of the plate-shaped member 510 than the pressing portion 522 surrounding an edge portion of the second surface 512 of the plate-shaped member 510 in a frame shape.

In order to mold the frame body 420 or 520 integrally with the plate-shaped member 410 or 510 having the bent portions 413 and 414 or the bent portion 513 as described above, it is possible to use a mold capable of accommodating the curved glass.

In accordance with the practical use of the above-described organic EL, it is expected that there will be a demand for designs using curved glass for display devices. It is undeniable that the use of the bent glass for the display device also further complicates handling the glass part during transportation, assembly, and installation in a vehicle or the like, and the object such as suppression of twisting of the glass part during assembly and installation.

According to the panel body 5 of the second modification, the plate-shaped member 510 includes a plate-shaped portion 510a, a plate-shaped portion 510b adjacent to the plate-shaped portion 510a on one end side, and a bent portion 513 connecting the plate-shaped portion 510a and the plate-shaped portion 510b to each other at a predetermined angle. By integrally molding the frame body 520 as described above, the plate-shaped member 510 having such a bent portion 513 can be applied to the panel body 5.

According to the panel body 5 of the second modification, the angle formed by the plate-shaped portion 510a and the plate-shaped portion 510b is less than 95°. In this manner, the frame body 520 can also be integrally molded with a bent glass forming an angle close to the right angle while following the bent glass.

According to the panel body 4 of the second modification, the plate-shaped member 410 further includes, in addition to the plate-shaped portions 410a and 410b and the bent portion 413, a plate-shaped portion 410c adjacent to the plate-shaped portion 410a on the other end side opposite to the plate-shaped portion 410b, and a bent portion 414 connecting the plate-shaped portion 410a and the plate-shaped portion 410c at a predetermined angle. In this manner, the frame body 420 can also be integrally molded with a bent glass having a complicated shape in which both sides are bent while following the bent glass.

According to the panel body 4 or 5 of the second modification, the effects that are the same as those of the panel body 10 of the above-described embodiment are obtained.

In the above-described embodiment and the first and second modifications thereof, the frame bodies 14 and 220 to 520 surrounding the end surfaces of the plate-shaped members 12 and 210 to 510 in a frame shape have been described. However, the frame body included in the panel body may have, for example, a partially extended shape together with the frame-shaped portion surrounding the end surface of the plate-shaped member, and this may constitute a part of the design of the second surface panel and the housing of the display device to which the panel body is assembled.

In addition, in the above-described embodiment and the first and second modifications thereof, the examples of the panel bodies 10 and 2 to 5 including the plate-shaped members 12 and 210 to 510 having a substantially rectangular shape have been described. However, the plate-shaped member used for the panel body may have a shape other than the rectangular shape, such as a circular shape, an elliptical shape, or another polygonal shape.

### Second Embodiment

Next, a display device including any of the panel bodies 10 and 2 to 5 described in the embodiment and modifications thereof described above will be described. In the present embodiment, a mode in which the display device including the panel body 10 will be described as an example. However, the display device may include any of the panel bodies 2 to 5.

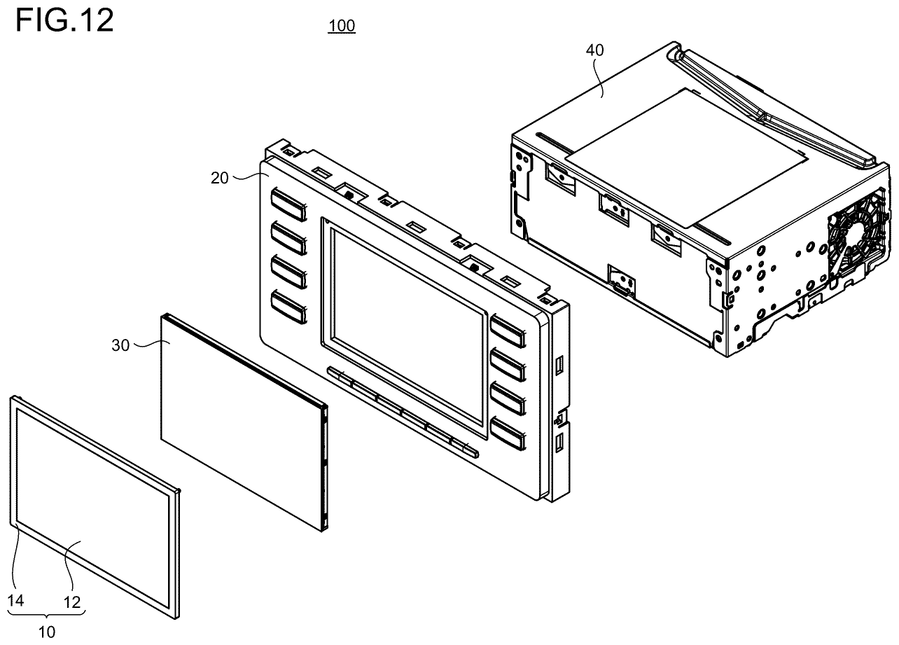

FIGS. 11 and 12 are schematic views illustrating an example of a display device 100 according to the present embodiment. FIG. 11 is a schematic view illustrating an example of an overall configuration of the display device 100. FIG. 12 is a schematic view illustrating the display device 100 disassembled into parts constituting the display device 100.

The display device 100 is a display device that displays various types of information.

The display device 100 includes a panel body 10, a holder 20, a liquid crystal panel 30, and a main body 40.

The panel body 10 is a member provided in a panel portion of the display device 100. The panel body 10 includes a plate-shaped member 12 and a frame body 14. The plate-shaped member 12 provided in the display device 100 is a plate-shaped glass made of glass.

The holder 20 is a member that holds the panel body 10. The holder 20 is, for example, an escutcheon. The escutcheon is a part for holding the holder 20 or for holding and covering the holder 20 for protection.

The liquid crystal panel 30 is a display that displays various images. The liquid crystal panel 30 is, for example, a liquid crystal display, an organic electro-luminescence (EL), or the like.

The main body 40 includes a control unit or the like that controls each unit of the display device 100.

The display device 100 is manufactured, for example, by assembling the holder 20 to which the panel body 10 and the liquid crystal panel 30 are assembled to the main body 40.

As described above, the display device 100 of the present embodiment includes a panel body 10. The panel body 10 includes a plate-shaped member 12, and a frame body 14 made of CFRTP and integrally molded with the plate-shaped member 12 and covering an end surface of the plate-shaped member 12 without discontinuity.

Here, in recent years, as the screen size of the display device increases, it is more difficult to transport and assemble the plate-shaped member 12. In addition, the number of plate-shaped members 12 mounted on various display devices 100 such as a monitor of a navigation system for a vehicle is increasing.

As described above, in a case where the display device is used as an on-vehicle device, when the display device is assembled to the vehicle, slight diagonal twisting may occur in the plate-shaped member 12 due to a vehicle bracket, another interior part, and the like. In this case, there is a concern that the glass may be damaged instantaneously or over time

On the other hand, the display device used as the in-vehicle device is also required to satisfy collision safety such as Federal Motor Vehicle Safety Standards in the United States and Regulations for Interior Fittings in Japan, Europe, and the like.

For this reason, a technique is known in which a metal-pressed product, a die-cast product, or the like is added to a glass part to enhance strength. In recent years, for example, die-cast products made of magnesium, which is lightweight and has high strength, have attracted attention. However, it takes a long tack time to manufacture a metal part made of magnesium or the like, and the production number is limited. In addition, there is also a problem that many portions are disposed of by deburring or the like, resulting in an increase in cost.

In addition, there is disclosed a configuration in which a part for protection such as a cushion material or a protective member is added to suppress damage to a glass part. In addition, there is disclosed a configuration in which a metal part such as a press or a cast is added to improve a strength of a product. In addition, as a measure against an unexpected situation, a protective film for preventing scattering is attached to a glass surface. However, such a configuration may increase the number of parts constituting the display device, making the device configuration complicated. For this reason, the display device of the related art may be difficult to handle, such as damage or complication of the device.

On the other hand, the display device 100 of the present embodiment includes a panel body 10 and a holder 20. The panel body 10 includes a plate-shaped member 12, and a frame body 14 made of a carbon fiber-reinforced resin and integrally molded with the plate-shaped member 12 and covering an end surface of the plate-shaped member 12 without discontinuity.

Since the panel body 10 includes a plate-shaped member 12, and a frame body 14 made of a carbon fiber-reinforced resin and integrally molded with the plate-shaped member 12 and covering the end surface of the plate-shaped member 12 without discontinuity as described above, it is possible to increase the strength of the panel body 10 and improve the torsional rigidity of the entire plate-shaped member 12.

Specifically, since the frame body 14 is integrally molded around the plate-shaped member 12, the torsional rigidity of the entire panel body 10 is improved. This suppresses, for example, the diagonal twisting of the rectangular plate-shaped member 12, thereby suppressing damage to the plate-shaped member 12. In addition, since the end surface of the plate-shaped member 12 is protected by the frame body 14, damage such as a crack or a chip in the end surface of the plate-shaped member 12 is suppressed, and the overall strength of the plate-shaped member 12 against impact, collision, and the like is improved.

In addition, since the torsional rigidity of the entire panel body 10 is improved, the panel body 10 is easily assembled to the holder 20 during manufacturing. In addition, since the torsional rigidity of the entire panel body 10 can be improved and the damage to the plate-shaped member 12 can be suppressed, it is possible to suppress an occurrence of damage such as a crack or a chip in the plate-shaped member 12 at the time of assembling the panel body 10 to the holder 20 or attaching the panel body 10 to a vehicle or the like during transportation or manufacturing.

In addition, even in a case where at least one of the part for protection such as a cushion material or a protective member, the metal part for improving a strength of a product, and the protective film for preventing scattering is omitted, the strength of the plate-shaped member 12 can be improved, and the complication of the device configuration can be suppressed.

Therefore, the display device 100 of the present embodiment can be easily handled during transportation and assembly.

Therefore, the present embodiment can provide the display device 100 that is easy to handle.

In addition, the display device 100 of the present embodiment can suppress damage to the plate-shaped member 12 without adding a protective member or the like for suppressing the damage. Therefore, in addition to the above-described effects, the display device 100 of the present embodiment can simplify the device configuration of the display device 100 and simplify the manufacturing process.

In addition, the display device 100 of the present embodiment can include a panel body 10 using a frame body 14 made of CFRTP as an alternative to a metal part such as a magnesium die-cast product. Therefore, in addition to the above-described effects, the display device 100 of the present embodiment can reduce the weight of the display device 100 while maintaining the strength of the panel body 10.

In addition, since the frame body 14 of the display device 100 of the present embodiment covers the end surface of the plate-shaped member 12 without discontinuity, designability can be added to the panel body 10. For example, the frame body 14 of the present embodiment can be directly applied to the display device 100 without performing surface coating or the like.

### Third Embodiment

In the present embodiment, a mode in which the frame body 14 in the above-described embodiment has an assembling portion will be described. The assembling portion is a portion used for assembling the frame body 14 to another member constituting the display device 100.

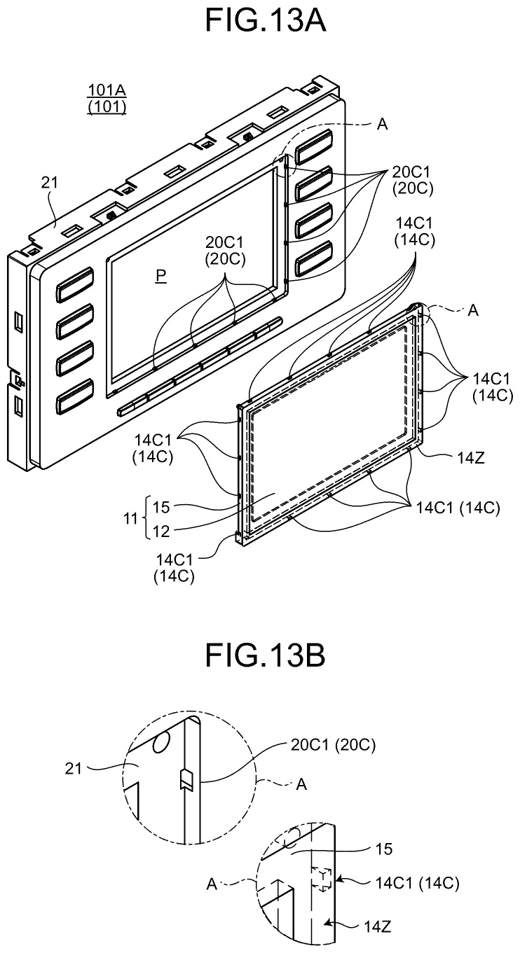

FIGS. 13A and 13B are views for explaining an example of a display device 101 of the present embodiment. The display device 101 has the same configuration as the display device 100 of the above-described embodiment except that a frame body 15 corresponding to the frame body 14 in the display device 100 of the above-described embodiment further includes an assembling portion, and a holder 21 corresponding to the holder 20 further includes an assembled portion. The same reference numerals are given to the same configurations as those in the above-described embodiment, and the detailed description thereof will be omitted.

FIGS. 13A and 13B are schematic views for an example of a display device 101A of the present embodiment. The display device 101A is an example of the display device 101. FIG. 13A is a perspective view of the display device 101A. FIG. 13B is an enlarged view of a part (a portion in area A) of the display device 101A.

As illustrated in FIG. 13A, the display device 101A includes a panel body 11, a holder 21, a liquid crystal panel 30, and a main body 40. The liquid crystal panel 30 and the main body 40 are the same as those in the above-described embodiment, and thus, the illustration thereof is omitted.

The panel body 11 is similar to the panel body 10 of the above-described embodiment except that a frame body 15 having an assembling portion 14C is provided instead of the frame body 14. The frame body 15 is similar to the frame body 14 of the above-described embodiment except that the assembling portion 14C is provided. That is, similarly to the frame body 14, the frame body 15 is a frame body made of CFRTP and integrally molded with the plate-shaped member 12 and covering an end surface of the plate-shaped member 12 without discontinuity.

The assembling portion 14C is a partial portion of the frame body 15, and is a portion used for positioning or fixing the frame body 15 when assembled to the holder 21. The assembling portion 14C is integrally molded with a main frame body 14Z of the frame body 15. The main frame body 14Z is a frame-shaped portion of the frame body 15 having a shape along the outer periphery of the plate-shaped member 12 and covering the end surface of the plate-shaped member 12 without discontinuity. The assembling portion 14C is engaged with or fitted to an assembled portion 20C provided in the holder 21.

The holder 21 is the same as the holder 20 of the above-described embodiment except that the assembled portion 20C is provided. The assembled portion 20C is a partial portion of the holder 21, and is a portion engaged with or fitted to the assembling portion 14C of the frame body 15.

As illustrated in FIG. 13A, one or a plurality of assembling portions 14C1 are provided in the frame body 15 of the panel body 11. The assembling portion 14C1 is an example of the assembling portion 14C. Also, as illustrated in FIG. 13A, one or a plurality of assembled portions 20C1 are provided in the holder 21. The assembled portion 20C1 is an example of the assembled portion 20C.

FIG. 13A illustrates, as an example, a configuration in which four assembling portions 14C1 are provided on each of the four sides constituting the outer periphery of the rectangular frame body 15. In addition, FIG. 13A illustrates, as an example, a configuration in which four assembled portions 20C1 are provided on each of the four sides constituting the outer periphery of an opening P provided in the holder 21. The opening P is an opening provided in the holder 21, and is a region to which the panel body 11 is assembled.

The positions of the assembling portions 14C1 and the assembled portions 20C1 may be any positions as long as they are engaged with each other, and are not limited to the mode illustrated in FIG. 13A. In addition, the number of assembling portions 14C and the number of assembled portions 20C may be any number as long as the assembling portions 14C1 and the assembled portions 20C1 are engaged with each other in at least one pair, and is not limited to the mode illustrated in FIG. 13A.

As illustrated in FIG. 13B, the assembled portion 20C1 of the holder 21 and the assembling portion 14C1 of the panel body 11 are positioned and shaped to get involved, that is, engaged with each other, when the panel body 11 and the holder 21 are assembled at the correct position.

For example, as illustrated in FIG. 13B, the assembling portion 14C1 protrudes outward from the rectangular main frame body 14Z in a side surface direction of the frame body 15, and has a claw shape that constitutes a locked state where the assembling portion 14C1 is stopped by being caught by the assembled portion 20C1 when assembled. The assembled portion 20C1 is provided on the outer peripheral surface of the holder 21 facing the rectangular opening P for assembling the panel body 11, and has a recessed shape recessed toward the direction away from the opening P. In addition, the assembled portion 20C1 has a shape that constitutes a locked state where the assembling portion 14C1 is hooked and stopped when the panel body 11 is assembled. That is, the assembling portion 14C1 having a convex shape and the assembled portion 20C1 having a concave shape are configured to be engaged with each other.

As described above, in the display device 101A of the present embodiment, the frame body 15 has the assembling portion 14C1 with respect to the holder 21. In addition, the holder 21 includes an assembled portion 20C1 for the assembling portion 14C1 to be engaged therewith.

Therefore, when the panel body 11 is assembled to the holder 21, the panel body 11 is assembled to the holder 21 such that the assembling portion 14C1 of the frame body 15 and the assembled portion 20C1 of the holder 21 are engaged with each other, whereby the panel body 11 can be easily and accurately assembled to the holder 21.

Therefore, in addition to the effects of the above-described embodiment, the display device 101A of the present embodiment can have a configuration in which the panel body 11 can be easily assembled to the holder 21.

In addition, in the display device 101A of the present embodiment, the user can assemble the panel body 11 to the holder 21 by assembling the panel body 11 to the holder 21 such that the assembling portion 14C1 of the frame body 15 and the assembled portion 20C1 of the holder 21 are engaged with each other. Therefore, in addition to the above-described effects, the display device 101A of the present embodiment can easily and accurately fix and assemble the panel body 11 to the holder 21 without separately preparing a detailed instruction for a user in charge of assembly and a part such as a double-sided tape, an adhesive, or a screw for assembly.

The assembling portion 14C1 and the assembled portion 20C1 are positioned and shaped to be engaged with each other when the panel body 11 and the holder 21 are assembled at the correct position. Therefore, in addition to the above-described effects, the display device 101A of the present embodiment can support reduction in positioning work and simplification of work at the time of assembling the panel body 11 to the holder 21.

In the display device 101A of the present embodiment, the assembling portion 14C1 is integrally molded with the main frame body 14Z of the frame body 15. In addition, in the display device 101A of the present embodiment, the main frame body 14Z and the assembling portion 14C1 of the frame body 15 are made of CFRTP that covers the end surface of the plate-shaped member 12 without discontinuity, similarly to the frame body 14 of the above-described embodiment. Therefore, in addition to the effects of the above-described embodiment, the present embodiment can provide the display device 101A that suppresses damage to the plate-shaped member 12 and is easy to handle during assembly.

### Third Modification

In the above-described embodiment, a mode in which the assembling portion 14C has a shape protruding outward in the side surface direction of the frame body 15 from the rectangular main frame body 14Z has been described as an example. Furthermore, in the above-described embodiment, a mode in which the assembled portion 20C is provided on the outer peripheral surface of the holder 21 facing the opening P and has a recessed shape recessed toward the direction away from the opening P has been described as an example.

However, the assembling portion 14C and the assembled portion 20C may have any configuration as long as they are engaged with or fitted to each other, and the protruding direction or the recessed direction and the shape are not limited to the above-described embodiment.

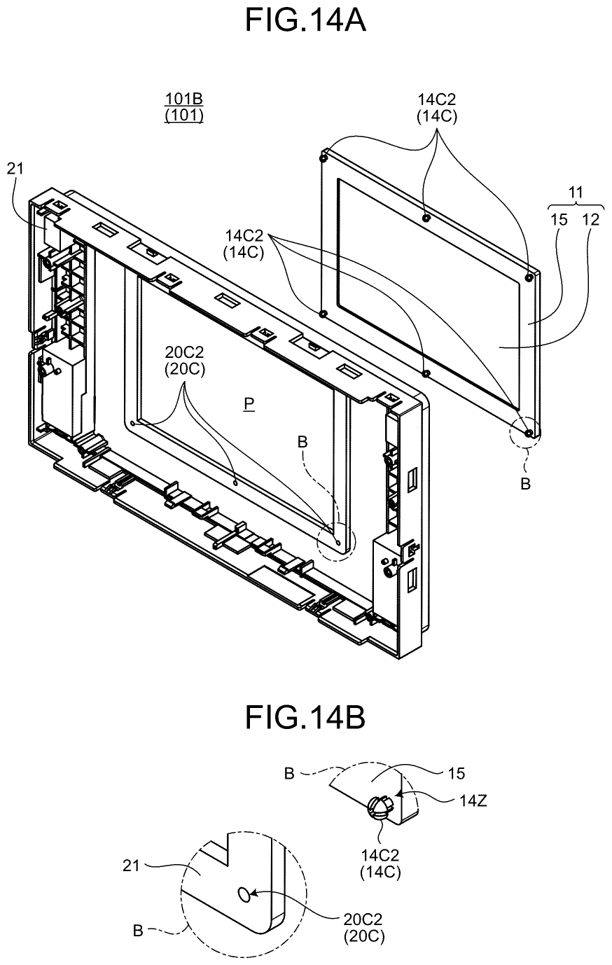

For example, the assembling portion 14C and the assembled portion 20C may be those illustrated in FIGS. 14A and 14B.

FIGS. 14A and 14B are views for explaining an example of a display device 101B of the present modification. The display device 101B is an example of the display device 101. FIG. 14A is a perspective view of the display device 101B. FIG. 14B is an enlarged view of a part (a portion in area B) of the display device 101B. The same reference numerals are given to the same configurations as those in the embodiments and modifications thereof described above, and the detailed description thereof will be omitted.

The frame body 15 of the panel body 11 of the present modification includes an assembling portion 14C2 instead of the assembling portion 14C1. In addition, the holder 21 of the present modification includes an assembled portion 20C2 instead of the assembled portion 20C1. The assembling portion 14C2 is an example of the assembling portion 14C, and the assembled portion 20C2 is an example of the assembled portion 20C.

FIG. 14A illustrates, as an example, a configuration in which three assembling portions 14C2 are provided on each of two sides parallel to each other among the four sides constituting the outer periphery of the rectangular frame body 15. In addition, FIG. 14A illustrates, as an example, a configuration in which three assembled portions 20C2 are provided on each of two sides parallel to each other among the four sides constituting the outer periphery of the opening P provided in the holder 21. The positions and the numbers of the assembling portions 14C2 and the assembled portions 20C2 may be any positions and numbers as long as they are engaged with each other, and are not limited to the mode illustrated in FIG. 14A.

As illustrated in FIG. 14B, the assembled portion 20C2 of the holder 21 and the assembling portion 14C2 of the panel body 11 are positioned and shaped to be engaged with each other when the panel body 11 and the holder 21 are assembled at the correct position.

For example, as illustrated in FIG. 14B, the assembling portion 14C2 protrudes from the rectangular main frame body 14Z toward the holder 21, and has a claw shape that constitutes a locked state where the assembling portion 14C2 is stopped by being caught by the assembled portion 20C1 when assembled. The assembled portion 20C2 is provided on a surface of the holder 21 facing the panel body 11, and has a recessed shape recessed in a direction away from the panel body 11. In addition, the assembled portion 20C2 has a shape that constitutes a locked state where the assembling portion 14C2 is hooked and stopped when the panel body 11 is assembled. That is, the assembling portion 14C2 having a convex shape and the assembled portion 20C2 having a concave shape are configured to be engaged with each other.

In this manner, the assembling portion 14C2 of the frame body 15 and the assembled portion 20C2 of the holder 21 may have any configuration as long as they are engaged with each other, and one has a convex shape and the other has a concave shape along the installation direction. In such a shape as well, the effects that are the same as those of the second embodiment can be obtained.

### Fourth Modification

In the present modification, an assembling portion 14C and an assembled portion 20C having shapes different from those in the second embodiment and the modification thereof will be described.

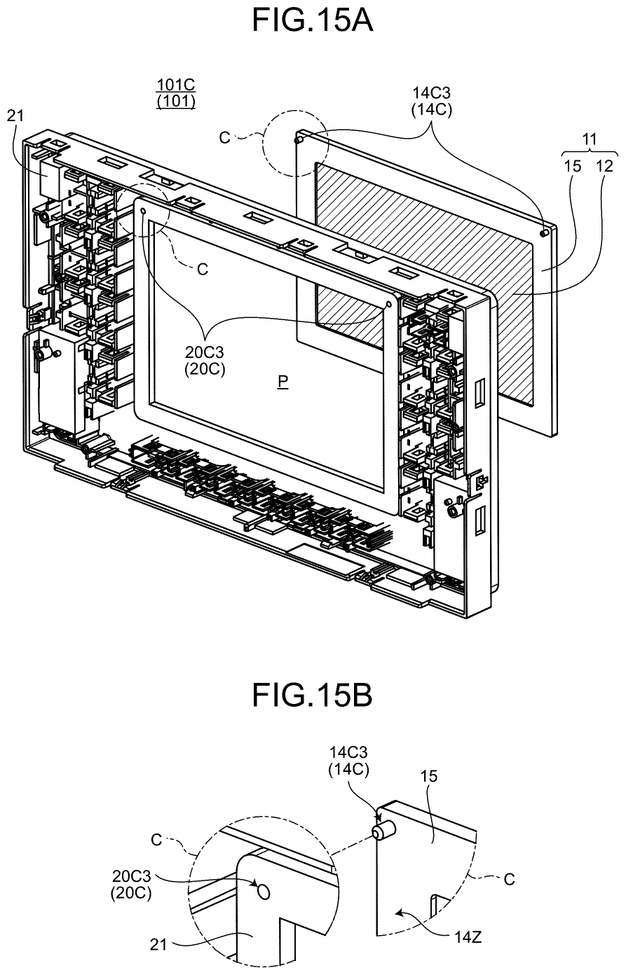

FIGS. 15A and 15B are views for explaining an example of a display device 101C of the present modification. The display device 101C is an example of the display device 101. FIG. 15A is a perspective view of the display device 101C. FIG. 15B is an enlarged view of a part (region C) of the display device 101C. The same reference numerals are given to the same configurations as those in the embodiments and modifications thereof described above, and the detailed description thereof will be omitted.

The frame body 15 of the panel body 11 of the present modification includes an assembling portion 14C3 instead of the assembling portion 14C1. In addition, the holder 21 of the present modification includes an assembled portion 20C3 instead of the assembled portion 20C1. The assembling portion 14C3 is an example of the assembling portion 14C, and the assembled portion 20C3 is an example of the assembled portion 20C.

FIG. 15A illustrates, as an example, a configuration in which one assembling portion 14C3 is provided at each of two of the four vertexes formed by the four sides constituting the outer periphery of the rectangular frame body 15. In addition, FIG. 15A illustrates, as an example, a configuration in which one assembled portion 20C3 is provided at each of two of the four vertexes formed by the four sides constituting the outer periphery of the opening P provided in the holder 21 at a position facing the assembling portion 14C3 when assembled. The positions and the numbers of the assembling portions 14C3 and the assembled portions 20C3 may be any positions and numbers as long as they are fitted to each other, and are not limited to the mode illustrated in FIG. 15A.

As illustrated in FIG. 15B, the assembled portion 20C3 of the holder 21 and the assembling portion 14C3 of the panel body 11 are positioned and shaped to be fitted to each other when the panel body 11 and the holder 21 are assembled at the correct position.

For example, as illustrated in FIG. 15B, the assembling portion 14C3 protrudes from the rectangular main frame body 14Z toward the holder 21, and has a shape that constitutes a fitted state where the assembling portion 14C3 is fitted to the assembled portion 20C3 when assembled. FIG. 15B illustrates, as an example, a mode in which the assembling portion 14C3 is a columnar region protruding from the main frame body 14Z toward the holder 21.

The assembled portion 20C3 is provided on a surface of the holder 21 facing the panel body 11, and has a recessed shape recessed in a direction away from the panel body 11. In addition, the assembled portion 20C3 has a shape that constitutes a fitted state where the assembled portion 20C3 is fitted to the assembling portion 14C3 when the panel body 11 is assembled. That is, the assembling portion 14C3 having a convex shape and the assembled portion 2003 having a concave shape are configured to be fitted to each other. In other words, the outer peripheral surface of the assembling portion 14C3 and the outer peripheral surface of the assembled portion 20C3 are shaped to be smoothly continuous with each other in contact with each other when the panel body 11 is assembled to the holder 21.

In this manner, the assembling portion 14C3 of the frame body 15 and the assembled portion 20C3 of the holder 21 may be configured to be fitted to each other. For example, one of the assembling portion 14C3 and the assembled portion 20C3 may have a convex shape and the other may have a concave shape. In such a shape as well, the effects that are the same as those of the second embodiment can be obtained.

### Fifth Modification

In the present modification, an assembling portion 14C and an assembled portion 20C having shapes different from those in the second embodiment and the modification thereof will be described.

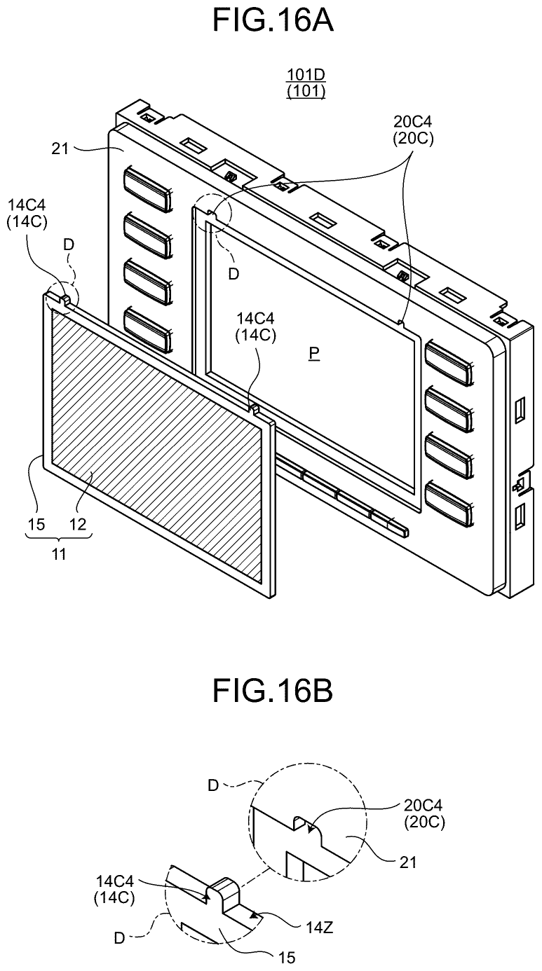

FIGS. 16A and 16B are views for explaining an example of a display device 101D of the present modification. The display device 101D is an example of the display device 101. FIG. 16A is a perspective view of the display device 101D. FIG. 16B is an enlarged view of a part (region D) of the display device 101D. The same reference numerals are given to the same configurations as those in the embodiments and modifications thereof described above, and the detailed description thereof will be omitted.

The frame body 15 of the panel body 11 of the present modification includes an assembling portion 14C4 instead of the assembling portion 14C1. In addition, the holder 21 of the present modification includes an assembled portion 20C4 instead of the assembled portion 20C1. The assembling portion 14C4 is an example of the assembling portion 14C, and the assembled portion 20C4 is an example of the assembled portion 20C.

FIG. 16A illustrates, as an example, a configuration in which one assembling portion 14C4 is provided at each of both end portions in the longitudinal direction on one of the four sides constituting the outer periphery of the rectangular frame body 15. In addition, FIG. 16A illustrates, as an example, a configuration in which the assembled portion 20C4 is provided at a position facing each of the assembling portions 14C4 on a side of the panel body 11 where the assembling portions 14C4 are provided among the four sides constituting the outer periphery of the opening P provided in the holder 21. The positions and the numbers of the assembling portions 14C4 and the assembled portions 20C4 may be any positions and numbers as long as they are fitted to each other, and are not limited to the mode illustrated in FIG. 16A.

As illustrated in FIG. 16B, the assembled portion 20C4 of the holder 21 and the assembling portion 14C4 of the panel body 11 are positioned and shaped to be fitted to each other when the panel body 11 and the holder 21 are assembled at the correct position.

For example, as illustrated in FIG. 16B, the assembling portion 14C5 is provided on the outer peripheral surface of the peripheral edge of the rectangular main frame body 14Z, and has a convex shape protruding in a direction away from the outer peripheral surface. FIG. 16B illustrates, as an example, a mode in which the assembling portion 14C4 is a convex region protruding from the main frame body 14Z in the side surface direction. That is, the assembling portion 14C4 has a shape that constitutes a fitted state where the assembling portion 14C4 is fitted to the assembled portion 20C4 when assembled to the holder 21.

The assembled portion 20C4 is provided on a surface of the holder 21 facing the panel body 11, and has a recessed shape recessed in a direction away from the panel body 11. In addition, the assembled portion 20C4 has a shape that constitutes a fitted state where the assembled portion 20C4 is fitted to the assembling portion 14C4 when the panel body 11 is assembled. That is, the assembling portion 14C4 having a convex shape and the assembled portion 20C4 having a concave shape are configured to be fitted to each other. In other words, the outer peripheral surface of the assembling portion 14C4 and the outer peripheral surface of the assembled portion 20C4 are shaped to be smoothly continuous with each other in contact with each other when the panel body 11 is assembled to the holder 21.

In this manner, the assembling portion 14C4 of the frame body 15 and the assembled portion 20C4 of the holder 21 may have any configuration as long as they are fitted to each other, and for example, one has a convex shape and the other has a concave shape. In such a shape as well, the effects that are the same as those of the second embodiment can be obtained.

### Sixth Modification

In the present modification, a frame body 14 and an assembled portion 20C having shapes different from those in the second embodiment and the modifications thereof will be described.

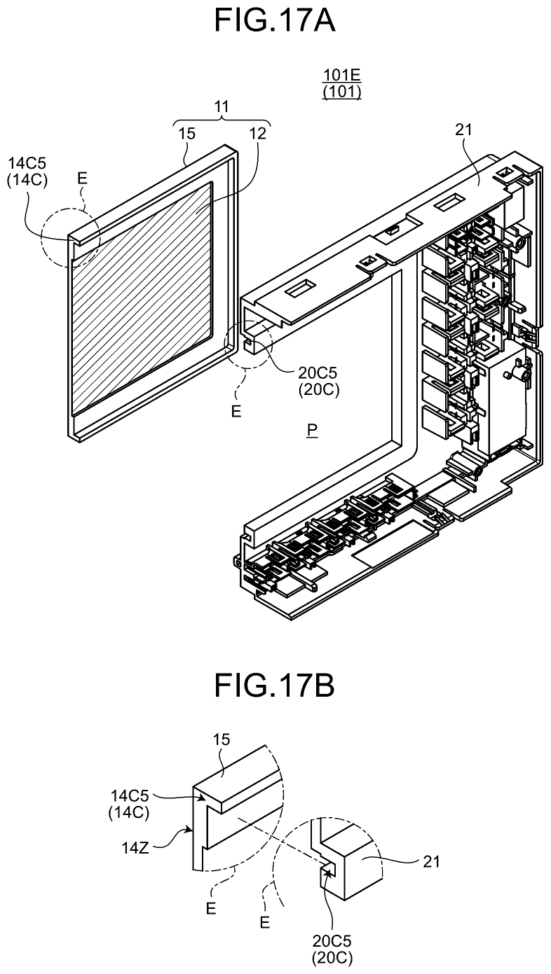

FIGS. 17A and 17B are views for explaining an example of a display device 101E of the present modification. The display device 101E is an example of the display device 101. FIG. 17A is a cross-sectional perspective view of the display device 101E. FIG. 17B is an enlarged cross-sectional view of a part (region E) of the display device 101E. The same reference numerals are given to the same configurations as those in the embodiments and modifications thereof described above, and the detailed description thereof will be omitted.

The frame body 15 of the panel body 11 of the present modification includes an assembling portion 14C5 instead of the assembling portion 14C1. In addition, the holder 21 of the present modification includes an assembled portion 20C5 instead of the assembled portion 20C1. The assembling portion 14C5 is an example of the assembling portion 14C, and the assembled portion 20C5 is an example of the assembled portion 20C.

FIG. 17A illustrates, as an example, a configuration in which the assembling portion 14C5 is provided over the entire peripheral region of the outer periphery of the rectangular frame body 15. In addition, FIG. 17A illustrates, as an example, a configuration in which the assembled portion 20C5 is provided along the outer periphery of the opening P provided in the holder 21 over the entire peripheral region of the outer periphery. The positions and the installation ranges of the assembling portion 14C5 and the assembled portion 20C5 may be any positions and ranges as long as they are fitted to each other, and are not limited to the mode illustrated in FIG. 17A.

As illustrated in FIG. 17B, the assembled portion 20C5 of the holder 21 and the assembling portion 1405 of the panel body 11 are positioned and shaped to be fitted to each other when the panel body 11 and the holder 21 are assembled at the correct position.

For example, as illustrated in FIG. 17B, the assembling portion 14C5 is a band-shaped region having a convex cross-sectional shape protruding toward the holder 21 from a surface of the rectangular main frame body 14Z facing the holder 21, and is continuously formed along the outer periphery of the main frame body 14Z.

The assembled portion 20C5 is provided on a surface of the holder 21 facing the panel body 11, and has a recessed shape that sandwiches the band-shaped assembling portion 14C5 having a convex cross-sectional shape from both directions intersecting the protruding direction of the convex cross-sectional shape. That is, the assembled portion 20C5 is provided on the surface of the holder 21 facing the panel body 11 and is a band-shaped region having a recessed cross-sectional shape.

In this manner, the assembling portion 14C5 of the frame body 15 and the assembled portion 20C5 of the holder 21 may have any configuration as long as they are fitted to each other, and for example, one has a band shape having a convex cross-sectional shape and the other has a band shape having a concave cross-sectional shape. In addition, the assembling portion 14C5 may have any configuration as long as it is provided over the entire peripheral region of the outer periphery of the frame body 15, and the assembled portion 20C5 may have any configuration as long as it is provided along the outer periphery of the opening P of the holder 21 over the entire peripheral region of the outer periphery. That is, the assembling portion 14C5 and the assembled portion 20C5 may be configured to be spigot-fitted along the outer periphery of the outer frame of the frame body 15 over the entire peripheral region.

With such a shape, the display device 101E of the present modification can obtain the effects that are the same as those of the second embodiment, and can realize the waterproof function.

### Seventh Modification

In the present modification, a frame body 14 and an assembled portion 20C having shapes different from those in the second embodiment and the modifications thereof will be described.

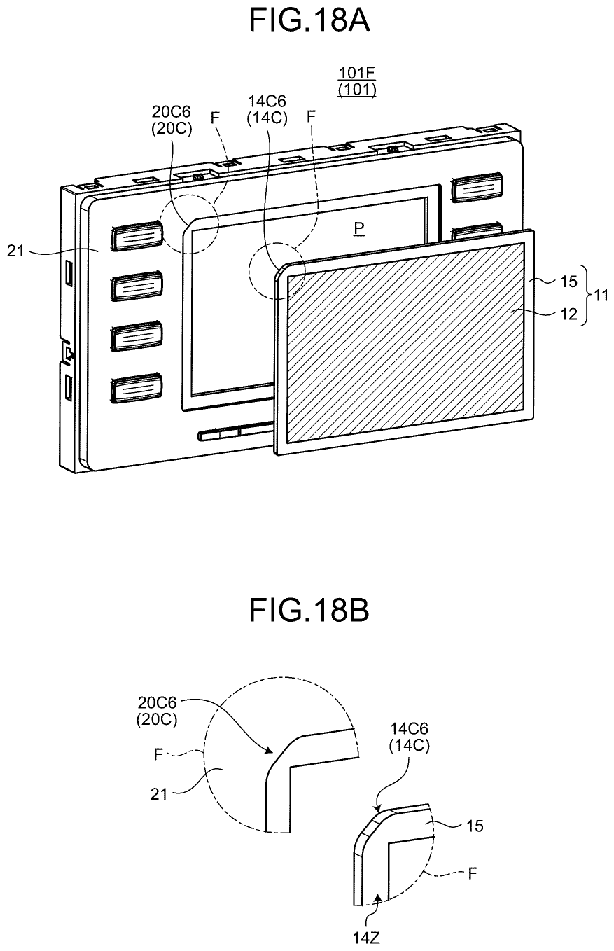

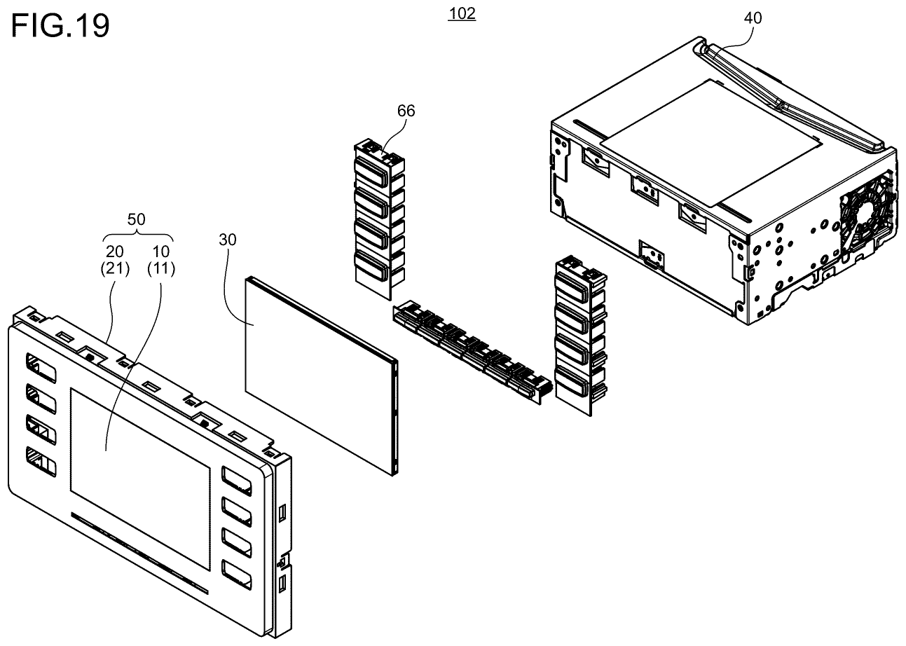

FIGS. 18A and 18B are views for explaining an example of a display device 101F of the present modification. The display device 101F is an example of the display device 101. FIG. 18A is a perspective view of the display device 101F. FIG. 18B is an enlarged view of a part (region F) of the display device 101F. The same reference numerals are given to the same configurations as those in the embodiments and modifications thereof described above, and the detailed description thereof will be omitted.

The frame body 15 of the panel body 11 of the present modification includes an assembling portion 14C6 instead of the assembling portion 14C1. In addition, the holder 21 of the present modification includes an assembled portion 20C6 instead of the assembled portion 20C1. The assembling portion 14C6 is an example of the assembling portion 14C, and the assembled portion 20C6 is an example of the assembled portion 20C.

As illustrated in FIG. 18A, the assembling portion 14C6 may be any portion as long as one of the four corners of the four sides of the outer periphery of the rectangular frame body 15 has a specific shape. FIG. 18A illustrates, as an example, a mode in which one of the four corners of the four sides of the outer periphery of the rectangular frame body 15 has a shape different from those of the other three corners. Specifically, as illustrated in FIG. 18B, for example, the assembling portion 14C6 is one of the four corners of the outer periphery of the rectangular frame body 15, which one corner having a 45-degree C. surface. Note that the angle of the C surface is an example, and is not limited to 45 degrees.

In addition, as illustrated in FIGS. 18A and 18B, the assembled portion 20C6 is one of the four corners on the outer periphery of the opening P provided in the holder 21, and is a portion having a shape along the outer periphery of the assembling portion 14C6. The assembled portion 20C6 is provided at a position where the assembling portion 14C6 should be disposed when the panel body 11 is correctly assembled to the holder 21.

In addition, as illustrated in FIG. 18A, the shape of the three corners other than the target corner where the assembling portion 14C6 is disposed on the outer periphery of the opening P of the holder 21 is different from that of the outer periphery of the assembled portion 20C6, and is a shape along the outer periphery of each of the three corners other than the assembling portion 14C6 on the outer periphery of the frame body 15.

With such a shape, the display device 101F of the present modification can obtain the effects that are the same as those of the second embodiment, and can suppress the panel body 11 from being assembled to the holder 21 at an incorrect angle.

### Fourth Embodiment

In the embodiments and the modifications thereof described above, the mode in which the panel body 10 (the panel body 11) and the holder 20 (the holder 21) are configured as separate bodies and assembled at the time of manufacturing the display device 100 (the display device 101) or the like has been described.

The panel body 10 and the holder 20, or the panel body 11 and the holder 21 may have any configuration as long as they are integrally molded.

FIG. 19 is a schematic view of an example of a display device 102 of the present embodiment. FIG. 19 is a schematic view illustrating the display device 102 disassembled into parts constituting the display device 102.

The display device 102 is similar to the display device 100 of the above-described embodiment and the display devices 101 of the above-described modifications except that an integrally molded body 50 in which the panel body 10 and the holder 20 are integrally molded is provided.

FIG. 19 illustrates an example in which the display device 102 further includes an accessory member 66. The accessory member 66 is a member provided with a button for receiving an operation performed by a user. Similarly, each of the display device 100 and the display device 101 may further include another member such as an accessory member 66.

The integrally molded body 50 is formed by integrally molding the panel body 10 and the holder 20. Also, the integrally molded body 50 may be formed by integrally molding the panel body 11 and the holder 21.

The integrally molded body 50 may be manufactured, for example, by using insert molding or the like. For example, the integrally molded body 50 may be manufactured by using insert molding or the like in which the panel body 10 or the panel body 11 manufactured in the same manner as in the above-described embodiment is placed in a mold again, and the heated and melted resin material of the holder 20 or the holder 21 is injected into the mold.

As described above, the display device 102 of the present embodiment includes an integrally molded body 50 in which the panel body 10 and the holder 20 or the panel body 11 and the holder 21 are integrally molded.

Therefore, in addition to the effects of the embodiment and modifications thereof described above, the present embodiment can provide the display device 102 that further suppresses damage and is easier to handle. In addition, by forming the integrally molded body 50, designability can be added to the panel body 10 and the holder 20 or the panel body 11 and the holder 21.

In the embodiments and modifications thereof described above, the frame body 14 and the frame body 15 each surrounding the end surface of the plate-shaped member 12 in a frame shape have been described. However, the frame body included in each of the panel body 10 and the panel body 11 may have, for example, a partially extended shape or the like together with the frame-shaped portion surrounding the end surface of the plate-shaped member 12, and this may constitute a part of the design of the first surface panel and the housing of each of the display device 100, the display device 101, and the display device 102 manufactured when assembled.

In the embodiments and modifications thereof described above, the panel body 10 and the panel body 11 each including the plate-shaped member 12 having a substantially rectangular shape have been described as examples. However, the plate-shaped member 12 used for each of the panel body 10 and the panel body 11 may have a shape other than the rectangular shape, such as a circular shape, an elliptical shape, or another polygonal shape.

The panel body according to the present disclosure is easy to handle.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A panel body comprising:
a plate-shaped member; and
a frame body made of a carbon fiber-reinforced resin and integrally molded with the plate-shaped member, wherein
the frame body covers an end surface of the plate-shaped member without discontinuity.

2. The panel body according to claim 1, wherein
the frame body is configured to sandwich the plate-shaped member from front and back surfaces thereof.

3. The panel body according to claim 2, wherein
the frame body includes:
a first pressing portion extending from the end surface of the plate-shaped member toward a first surface and surrounding an edge portion of the first surface in a frame shape; and
a second pressing portion extending from the end surface of the plate-shaped member toward the back surface and surrounding an edge portion of the back surface in a frame shape.

4. The panel body according to claim 1, wherein
the plate-shaped member has a thickness of 3 mm or less.

5. The panel body according to claim 1, wherein
the plate-shaped member has a curved surface.

6. The panel body according to claim 1, wherein
the plate-shaped member includes:
a first surface;
a second surface adjacent to the first surface on one end side; and
a first bent portion connecting the first surface and the second surface at a predetermined angle.

7. The panel body according to claim 6, wherein an angle formed by the first surface and the second surface is less than 95°.

8. The panel body according to claim 7, wherein the first bent portion has a curved surface shape, and the first bent portion has a bending radius of less than 1.5 mm.

9. The panel body according to claim 6, wherein the plate-shaped member further includes:
a third surface adjacent to the first surface on other end side opposite to the second surface; and
a second bent portion connecting the first surface and the third surface at a predetermined angle.

10. The panel body according to claim 1, wherein
the plate-shaped member is made of glass, stone, wood, paper, or cloth.

11. The panel body according to claim 1, wherein
the frame body has anisotropy.

12. The panel body according to claim 1, wherein
the frame body is at least partially colored.

13. A display device comprising
the panel body according to claim 1, wherein
the plate-shaped member is a plate-shaped glass.

14. The display device according to claim 13, further comprising
a holder that holds the panel body, wherein the frame body includes an assembling portion with respect to the holder.

15. The display device according to claim 14, wherein
the assembling portion is integrally molded with a main frame body of the frame body.

16. The display device according to claim 14, wherein
the assembling portion has a shape to be engaged with or fitted to an assembled portion provided in the holder.

17. The display device according to claim 14, wherein
the panel body and the holder are integrally molded.

18. A method for manufacturing a panel body, the method comprising:
inserting a plate-shaped member into a first space formed by a first recessed portion and a second recessed portion of a mold, and bringing a first surface of the plate-shaped member into contact with a bottom portion of the first recessed portion, the mold including a first mold having the first recessed portion and a second mold having the second recessed portion disposed opposite to the first recessed portion;
pressing at least one of the first mold and the second mold in a direction in which they approach each other in a state where the plate-shaped member is sandwiched in the first space, and heating the mold to a temperature higher than or equal to a temperature at which the plate-shaped member is moldable and a melting temperature of a carbon fiber-reinforced resin;
sliding the bottom portion of the first recessed portion of the first mold toward the second recessed portion until a second surface of the plate-shaped member comes into contact with a bottom surface of the second recessed portion;
filling the carbon fiber-reinforced resin in a molten state into a second space that is a gap between the plate-shaped member and the mold in the first space and covers an end surface of the plate-shaped member; and
cooling the mold.

19. The method for manufacturing the panel body according to claim 18, wherein
the mold includes a plurality of filling ports at different positions where the carbon fiber-reinforced resin is filled into the space.
